(19) United States
(12) Patent Application Publication
(10) Pub. No.: US 2025/0176414 A1
(43) Pub. Date: May 29, 2025

(54) LIGHT EMITTING ELEMENT, DISPLAY DEVICE, AND ELECTRONIC APPARATUS

(71) Applicant: SONY SEMICONDUCTOR SOLUTIONS CORPORATION, KANAGAWA (JP)

(72) Inventors: SHINTARO YUMOTO, KANAGAWA (JP); YOSUKE MOTOYAMA, KANAGAWA (JP); KOJI MATSUSAKI, KUMAMOTO (JP)

(21) Appl. No.: 18/841,664

(22) PCT Filed: Feb. 8, 2023
(86) PCT No.: PCT/JP2023/004162

§ 371 Date: Aug. 26, 2024

(30) Foreign Application Priority Data
Mar. 2, 2022 (JP) 2022-031892

(51) Int. Cl. H10K 59/80

(52) U.S. Cl. CPC H10K 59/879; H10K 59/873

(57) ABSTRACT

A light emitting element (PX) according to an aspect of the present disclosure includes a light emitting unit (EL) that outputs light from a light emitting region, a first lens (61) having a hemispherical shape or a frustum shape and provided above the light emitting region of the light emitting unit (EL), and a second lens (91) having a frustum shape and provided above the first lens (61).

### FIELD

The present disclosure relates to a light emitting element, a display device, and an electronic apparatus.

### BACKGROUND

In recent years, a light emitting element having a light emitting unit of a current drive type and a display device including the light emitting element have been developed. For example, a light emitting element using an organic electroluminescence element (organic EL element) as a light emitting unit has attracted attention as a light emitting element capable of emitting light with high luminance by low-voltage direct current drive. In order to collect light from the light emitting element, for example, a single lens structure in which an OCL (on-chip microlens) having a hemispherical shape is mounted in one layer, and a double lens structure in which the OCL having a hemispherical shape is mounted in two layers have been proposed (see, for example, Patent Literature 1).

### CITATION LIST

### Patent Literature

Patent Literature 1: WO 2020/080022 A

### SUMMARY

### Technical Problem

However, in the single lens structure, the light transmitted through a color filter is collected by using refraction, but since a difference in refractive index between the OCL and an upper layer is small, there is light that cannot be refracted in a front direction, and light extraction efficiency (light emission efficiency) decreases. Therefore, the double lens structure is used to extract light in the front direction, but in the double lens structure, since the same OCLs having a hemispherical shape are mounted in the two layers, total reflection occurs at an edge portion of the OCL of the second layer, and the light extraction efficiency may be reduced.

Therefore, the present disclosure proposes a light emitting element, a display device, and an electronic apparatus capable of realizing improvement in light extraction efficiency.

### Solution to Problem

A light emitting element according to an aspect of the present disclosure includes a light emitting unit that outputs light from a light emitting region; a first lens having a hemispherical shape or a frustum shape and provided above the light emitting region of the light emitting unit; and a second lens having a frustum shape and provided above the first lens.

A display device according to an aspect of the present disclosure includes a plurality of light emitting elements, wherein the plurality of light emitting elements each include a light emitting unit that outputs light from a light emitting region, a first lens having a hemispherical shape or a frustum shape and provided above the light emitting region of the light emitting unit, and a second lens having a frustum shape and provided above the first lens.

An electronic apparatus according to an aspect of the present disclosure includes a display device including a plurality of light emitting elements, wherein the plurality of light emitting elements each include a light emitting unit that outputs light from a light emitting region, a first lens having a hemispherical shape or a frustum shape and provided above the light emitting region of the light emitting unit, and a second lens having a frustum shape and provided above the first lens.

### BRIEF DESCRIPTION OF DRAWINGS

FIG. 1 is a diagram illustrating an example of a schematic configuration of a display device according to an embodiment.

FIG. 2 is a diagram illustrating an example of a schematic configuration of a light emitting element according to the embodiment.

FIG. 3 is a diagram illustrating an example of a schematic configuration of the light emitting element according to the embodiment.

FIG. 4 is a diagram for explaining total reflection of a second lens according to the embodiment.

FIG. 5 is a diagram for explaining a base angle and a height of the second lens according to the embodiment.

FIG. 6 is a diagram illustrating a schematic configuration of a comparative example of the light emitting element according to the embodiment.

FIG. 7 is a diagram for explaining total reflection of the comparative example of the light emitting element according to the embodiment.

FIG. 8 is a diagram for explaining a comparison result according to the embodiment.

FIG. 9 is a diagram for explaining Modification 1 of the light emitting element according to the embodiment.

FIG. 10 is a diagram for explaining Modification 2 of the light emitting element according to the embodiment.

FIG. 11 is a diagram for explaining Modification 3 of the light emitting element according to the embodiment.

FIG. 12 is a schematic cross-sectional view for explaining a first example of a resonator structure.

FIG. 13 is a schematic cross-sectional view for explaining a second example of the resonator structure.

FIG. 14 is a schematic cross-sectional view for explaining a third example of the resonator structure.

FIG. 15 is a schematic cross-sectional view for explaining a fourth example of the resonator structure.

FIG. 16 is a schematic cross-sectional view for explaining a fifth example of the resonator structure.

FIG. 17 is a schematic cross-sectional view for explaining a sixth example of the resonator structure.

FIG. 18 is a schematic cross-sectional view for explaining a seventh example of the resonator structure.

FIG. 19 is a conceptual diagram for explaining a first example of a shift structure.

FIG. 20 is a conceptual diagram for explaining a second example of the shift structure.

FIG. 21 is a conceptual diagram for explaining a third example of the shift structure.

FIG. 22 is a conceptual diagram for explaining a fourth example of the shift structure.

FIG. 23 is a conceptual diagram for explaining a fifth example of the shift structure.

FIG. 24 is a conceptual diagram for explaining a sixth example of the shift structure.

FIG. 25 is a conceptual diagram for explaining a seventh example of the shift structure.

FIG. 26 is a diagram illustrating an example of an appearance of a smartphone.

FIG. 27 is a diagram illustrating an example of an appearance of a digital still camera.

FIG. 28 is a diagram illustrating an example of the appearance of the digital still camera.

FIG. 29 is a diagram illustrating an example of an appearance of a head mounted display.

FIG. 30 is a diagram illustrating an example of an appearance of a see-through head mounted display.

FIG. 31 is a diagram illustrating an example of an appearance of a television device.

FIG. 32 is a diagram illustrating an internal configuration of a vehicle.

FIG. 33 is a diagram illustrating the internal configuration of the vehicle.

### DESCRIPTION OF EMBODIMENTS

Hereinafter, embodiments of the present disclosure will be described in detail with reference to the drawings. Note that a light emitting element, a display device, an electronic apparatus, and the like according to the present disclosure are not limited by the embodiments. In addition, in the following embodiments, basically the same parts are denoted by the same reference numerals, and redundant description is omitted.

One or a plurality of embodiments (including examples and modifications) described below can each be implemented independently. On the other hand, at least some of the plurality of embodiments described below may be appropriately combined with at least some of other embodiments. The plurality of embodiments may include novel features different from each other. Therefore, the plurality of embodiments can contribute to solving different objects or problems, and can exhibit different effects.

The present disclosure will be described according to the following order of items.
1. Embodiments
1-1. Configuration Example of Display Device
1-2. Configuration Example of Light Emitting Element
1-3. Comparative Example of Light Emitting Element
1-4. Modifications of Light Emitting Element
1-5. Actions and Effects
2. Other Embodiments
3. Examples of Resonator Structure
4. Examples of Shift Structure
5. Application Example
6. Appendix

### 1. Embodiments

### 1-1. Configuration Example of Display Device

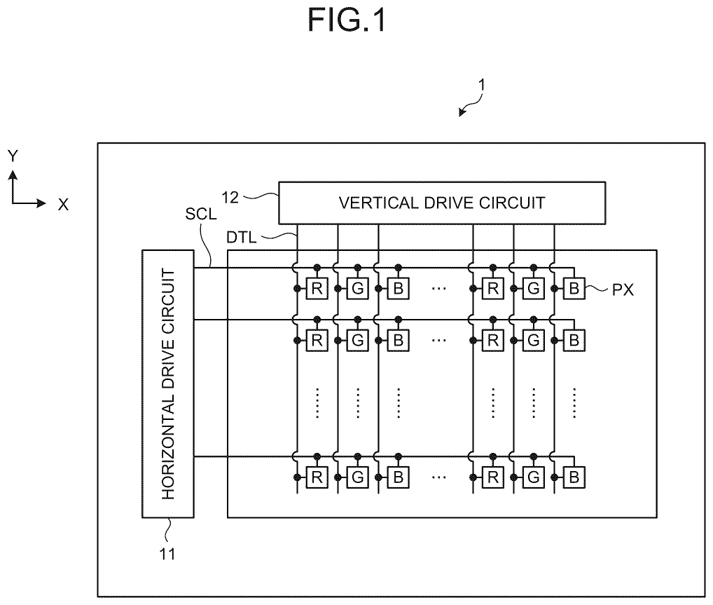

A configuration example of a display device 1 according to an embodiment will be described with reference to FIG. 1. FIG. 1 is a diagram illustrating an example of a schematic configuration of the display device 1 according to the embodiment.

As illustrated in FIG. 1, the display device 1 includes a plurality of light emitting elements PX arranged in a matrix, and a horizontal drive circuit 11 and a vertical drive circuit 12 for driving the light emitting elements PX. In the example of FIG. 1, a scanning line SCL is a line for scanning the light emitting element PX, and a signal line DTL is a line for supplying various voltages to the light emitting element PX. In addition, the display device 1 also includes a feeder line (not illustrated) that supplies a driving voltage or the like to the light emitting element PX. Note that in the example of FIG. 1, the horizontal drive circuit 11 and the vertical drive circuit 12 are each disposed on one edge side of the display device 1, but their arrangement is not particularly limited.

For example, M light emitting elements PX are arranged in a horizontal direction (X direction in FIG. 1), N light emitting elements PX are arranged in a vertical direction (Y direction in FIG. 1), and a total of M×N light emitting elements PX are arranged in a matrix. These light emitting elements PX function as respective pixels of the display device 1. In the example of FIG. 1, the light emitting elements PX corresponding to red display (R: wavelength 620 nm to 750 nm), green display (G: wavelength 495 nm to 570 nm), and blue display (B: wavelength 450 nm to 495 nm) are illustrated with reference signs R, G, and B, respectively. That is, the display device 1 is a display device capable of color display.

### 1-2. Configuration Example of Light Emitting Element

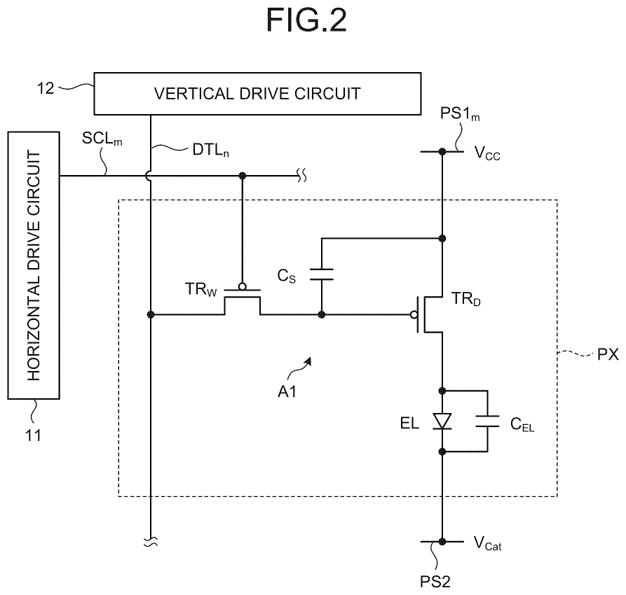

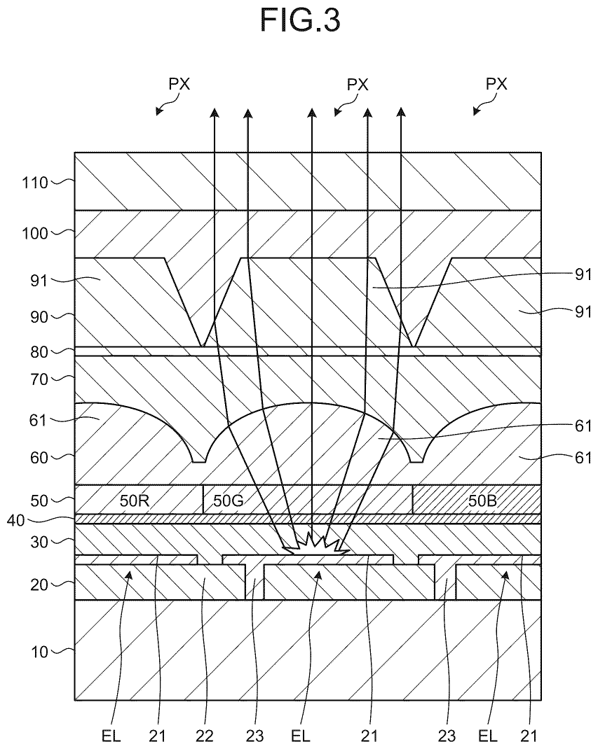

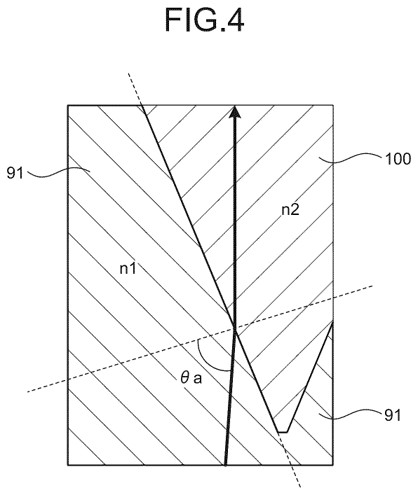

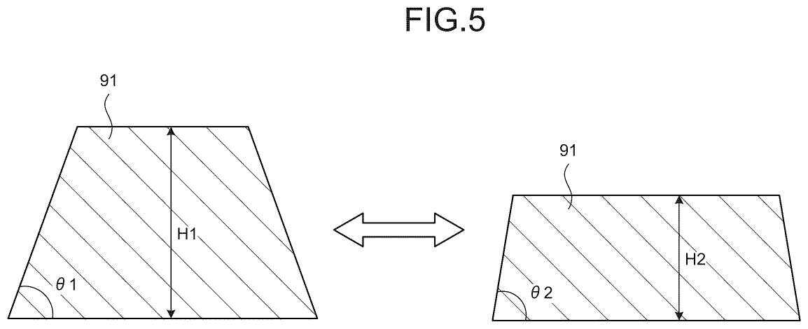

A configuration example of the light emitting element PX according to the embodiment will be described with reference to FIGS. 2 to 5. FIGS. 2 and 3 are diagrams each illustrating an example of a schematic configuration of the light emitting element PX according to the embodiment. FIG. 4 is a diagram for explaining total reflection of a second lens 91 according to the embodiment. FIG. 5 is a diagram for explaining a base angle and a height of the second lens 91 according to the embodiment. Note that in detail with respect to FIG. 2, FIG. 2 is a circuit diagram illustrating an example of a schematic configuration of the light emitting element PX, and in the example of FIG. 2, a connection relationship for one light emitting element PX, more specifically, the light emitting element PX in the m-th row and the n-th column is illustrated. In addition, FIG. 3 is a cross-sectional view illustrating an example of a schematic configuration of the light emitting element PX.

### (Circuit Diagram)

As illustrated in FIG. 2, the light emitting element PX includes a light emitting unit EL of a current drive type and a drive circuit A1 that controls light emission of the light emitting unit EL. The drive circuit A1 includes at least a write transistor TR_{W} for writing a video signal and a drive transistor TR_{D} for causing a current to flow through the light emitting unit EL. These include, for example, p-channel transistors.

The drive circuit A1 further includes a capacitor C_{S}. The capacitor C_{S} is used to hold a voltage (so-called gate-source voltage) of a gate electrode with respect to a source region of the drive transistor TR_{D}. At the time of light emission of the light emitting element PX, one source/drain region (the side connected to a feeder line PS1 in FIG. 2) of the drive transistor TR_{D} serves as the source region, and the other source/drain region serves as a drain region.

One electrode and the other electrode constituting the capacitor C_{S} are connected to one source/drain region and the gate electrode of the drive transistor TR_{D}, respectively. The other source/drain region of the drive transistor TR_{D} is connected to an anode electrode of the light emitting unit EL.

The light emitting element PX includes the light emitting unit EL including an organic electroluminescence element (organic EL element). The light emitting unit EL is a current drive-type light emitting unit whose light emission luminance changes according to the value of a flowing current. For example, the light emitting unit EL has a well-known configuration and structure including an anode electrode, a hole transport layer, a light emitting layer, an electron transport layer, and a cathode electrode.

The other end (specifically, the cathode electrode) of the light emitting unit EL is connected to a common feeder line PS2. A predetermined voltage V_{CATH} (for example, a ground potential) is supplied to the common feeder line PS2. Note that the capacitance of the light emitting unit EL is represented by a reference sign C_{EL}. In a case where a problem occurs in driving because the capacitance C_{EL} of the light emitting unit EL is small, an auxiliary capacitance connected in parallel to the light emitting unit EL may be provided as necessary.

The write transistor TR_{W} has a gate electrode connected to the scanning line SCL, one source/drain region connected to the signal line (data line) DTL, and the other source/drain region connected to the gate electrode of the drive transistor TR_{D}. As a result, a signal voltage from the signal line DTL is written to the capacitor C_{S} via the write transistor TR_{W}.

As described above, the capacitor C_{S} is connected between one source/drain region of the drive transistor TR_{D} and the gate electrode. A power supply voltage V_{CC} is applied from a power supply unit (not illustrated) to one source/drain region of the drive transistor TR_{D} via a feeder line PS1ₘ. When a video signal voltage V_{Sig} from the signal line DTL is written to the capacitor C_{S} via the write transistor TR_{W}, the capacitor C_{S} holds a voltage such as (V_{CC}-V_{Sig}) as the gate-source voltage of the drive transistor TR_{D}. A drain current I_{ds} expressed by the following Formula (1) flows through the drive transistor TR_{D}, and the light emitting unit EL emits light with luminance corresponding to a current value.

$${I}_{ds} = k \cdot μ \cdot {( ( {V}_{CC} - {V}_{Sig} ) - \vert {V}_{th} \vert )}^{2} \qquad ( 1 )$$

Here, μ: effective mobility, L: channel length, W: channel width, Vₜₕ: threshold voltage, Cₒₓ: (relative dielectric constant of gate insulating layer)×(dielectric constant of vacuum)/(thickness of gate insulating layer), and k≡(1/2)·(W/L)·Cₒₓ.

### (Cross-Sectional View)

As illustrated in FIG. 3, the display device 1 includes the plurality of light emitting elements PX. These light emitting elements PX each include a substrate 10, an anode layer 20, an organic layer 30, a cathode layer 40, a color filter layer (CF layer) 50, a first lens layer 60, a filling layer 70, a planarization layer 80, a second lens layer 90, a sealing layer 100, and a transparent substrate 110. Each light emitting element PX is configured such that the anode layer 20, the organic layer 30, the cathode layer 40, the color filter layer 50, the first lens layer 60, the filling layer 70, the planarization layer 80, the second lens layer 90, the sealing layer 100, and the transparent substrate 110 are sequentially stacked on the substrate 10.

The substrate 10 is a support that supports the plurality of light emitting elements PX arranged on one surface. The substrate 10 includes, for example, a control circuit (for example, the drive circuit A1) that controls driving of each light emitting element PX, but may include a power supply circuit that supplies power to each light emitting element PX and a multilayer wiring layer including various wirings.

The anode layer 20 is stacked on the substrate 10. The anode layer 20 includes a plurality of anode electrodes 21, an insulating layer 22, and a plurality of contact plugs 23. Each anode electrode 21 is provided on one surface (upper surface in FIG. 3) of the insulating layer 22 for each light emitting element PX. For example, the anode electrode 21 may be formed of a metal material and reflect light. The anode electrode 21 corresponds to a first electrode. The insulating layer 22 is stacked on the substrate 10. The insulating layer 22 may include, for example, a reflective layer. Each contact plug 23 electrically connects, for example, the anode electrode 21 and the drive circuit A1 for each light emitting unit EL. Note that the drive circuit A1 controls a light emission state of the light emitting unit EL in response to a signal from the outside.

The organic layer 30 is stacked on the anode layer 20. The organic layer 30 includes at least a light emitting layer, and is formed to emit white light, for example. Note that in the example of FIG. 3, the organic layer 30 is illustrated as one layer, but includes a plurality of layers including the light emitting layer.

The cathode layer 40 is stacked on the organic layer 30. The cathode layer 40 is formed of, for example, a material having high light transparency and conductivity (as an example, a transparent conductive material). The cathode layer 40 functions as a cathode electrode and corresponds to a second electrode.

Here, each light emitting unit EL is configured by sequentially stacking the organic layer 30 and the cathode layer 40 on the anode electrode 21 provided for each light emitting element PX. Light emitted in the organic layer 30 is output from a surface of the organic layer 30 on the cathode layer 40 side. In the example of FIG. 3, in an upper surface of the cathode layer 40 (or the organic layer 30), a facing surface corresponding to the anode electrode 21 is an upper surface of the light emitting unit EL, and the upper surface of the light emitting unit EL is a light emitting surface (light emitting region) from which the light emitting unit EL outputs light. A planar shape of the light emitting surface of the light emitting element PX generally follows a planar shape of the anode electrode 21.

The color filter layer 50 is stacked on the cathode layer 40. Specifically, the color filter layer 50 includes a color filter 50R for red display, a color filter 50G for green display, and a color filter 50B for blue display. Therefore, the display device 1 includes the light emitting element PX for red display, the light emitting element PX for green display, and the light emitting element PX for blue display.

The first lens layer 60 is stacked on the color filter layer 50. The first lens layer 60 includes a plurality of first lenses 61. These first lenses 61 have the same structure. The shape of the first lens 61 is a hemispherical shape, and as the first lens 61, for example, a microlens (on-chip microlens) is used. The refractive index of the first lens 61 is equal to or less than the refractive index of the color filter layer 50. The first lens 61 is formed by, for example, a reflow process (reflow method).

The filling layer 70 is stacked on the first lens layer 60. The filling layer 70 is provided between the first lens layer 60 and the second lens layer 90. The refractive index of the filling layer 70 is lower than the refractive index of the first lens 61. The filling layer 70 is formed of, for example, a material having high light transparency (as an example, a transparent resin material).

The planarization layer 80 is stacked on the filling layer 70. The planarization layer 80 planarizes the filling layer 70. The planarization layer 80 is formed of, for example, a material having high light transparency (as an example, a transparent resin material such as an acrylic resin). The refractive index of the planarization layer 80 is equal to or less than the refractive index of the filling layer 70.

The second lens layer 90 is stacked on the planarization layer 80. The second lens layer 90 includes a plurality of second lenses 91. These second lenses 91 have the same structure. The shape of the second lens 91 is a frustum shape, and as the second lens 91, for example, a microlens (on-chip microlens) is used. The refractive index of the second lens 91 is equal to or less than the refractive index of the planarization layer 80. The second lens 91 is formed by, for example, an etching process (for example, dry etching).

Here, the frustum is a truncated conical or pyramidal form. Examples of the frustum include a truncated pyramid and a truncated cone. As the truncated pyramid, for example, a frustum with an even number of angles such as a truncated quadrangular pyramid, a truncated hexagonal pyramid, or a truncated octagonal pyramid is used. In addition, depending on a desired light extraction direction, a frustum with an odd number of angles such as a truncated triangular pyramid or a truncated pentagonal pyramid may be used. As the truncated cone, for example, a truncated perfect-circular cone or a truncated elliptical cone may be used. In addition to a truncated pyramid or a truncated cone, a frustum having a special shape may be used.

The sealing layer 100 is stacked on the second lens layer 90. The sealing layer 100 is a layer for bonding the transparent substrate 110 to the second lens layer 90. The refractive index of the sealing layer 100 is lower than the refractive index of the second lens 91. The sealing layer 100 is formed of, for example, a material having high light transparency (as an example, a transparent adhesive material). As this material, for example, a thermosetting adhesive such as an acrylic adhesive, an epoxy-based adhesive, a urethane-based adhesive, a silicone-based adhesive, or a cyanoacrylate-based adhesive, an ultraviolet-curable adhesive, or the like is used.

The transparent substrate 110 is stacked on the sealing layer 100. The transparent substrate 110 protects the inside of the display device 1 from an external environment, and prevents ingress of moisture, oxygen, and the like into the organic layer 30, for example. The transparent substrate 110 is formed of, for example, a material having high light transparency and high gas barrier properties. As this material, for example, glass or the like is used.

Here, as illustrated in FIG. 4, when the refractive index of the second lens 91 is n1 and the refractive index of the sealing layer 100 is n2, the refractive index n2 of the sealing layer 100 is lower than the refractive index n1 of the second lens 91 (n2<n1). A critical angle θa is obtained from a relational expression of θa=arcsin (n2/n1). The critical angle θa is a minimum incident angle at the time of total reflection. For example, when n1 (refractive index of incident source) is 1.56 and n2 (refractive index of incident destination) is 1.36, θa=54 deg (n1=1.56, n2=1.36).

In addition, the base angle of the second lens 91 is set according to the height (length in the vertical direction in FIG. 3) of the first lens 61. The base angle of the second lens 91 is set to decrease as the height of the first lens 61 increases, and to increase as the height of the first lens 61 decreases. Note that the degree of inclination of an oblique side of the second lens 91 can be adjusted by changing the base angle of the second lens 91. The light extraction direction can be optimized by modifying the shape of the second lens 91 as described above.

For example, as illustrated in FIG. 5, a case where the base angle of the second lens 91 is θ1 and the height of the second lens 91 is H1 is compared with a case where the base angle of the second lens 91 is θ2 (θ2>θ1) and the height of the second lens 91 is H2 (H2<H1). The second lens 91 of θ1 and H1 is effective when the base angle is small, the height is high (for example, when the base angle is smaller than a predetermined base angle, the height is equal to or larger than a predetermined height), and the height of the first lens 61 is high (for example, the height is equal to or larger than 2.1 μm which is the predetermined height). On the other hand, the second lens 91 of θ2 and H2 is effective when the base angle is large, the height is low (for example, when the base angle is equal to or larger than the predetermined base angle, the height is lower than the predetermined height), and the height of the first lens 61 is low (for example, the height is lower than 2.1 μm which is the predetermined height).

According to the light emitting element PX having such a configuration, light in a range of 10° to 20° collected by the first lens 61 in the first stage can be collected to the front without being totally reflected by the second lens 91 in the second stage, so that the light extraction efficiency (light emission efficiency) can be improved. That is, by forming the second lens 91 in the second stage in a frustum shape, total reflection can be suppressed, and the light extraction efficiency in the front direction can be improved. In addition, by forming the second lens 91 in a frustum shape, it is possible to adjust the base angle of the frustum shape, that is, the degree of inclination of the oblique side according to the processing amount (for example, the etching amount) at the time of forming the second lens 91, and thus, it is possible to control total reflection according to the height of the first lens 61. In addition, the base area of the second lens 91 may be larger than the base area of the first lens 61. As a result, improvement in light extraction efficiency can be reliably realized.

Note that in two adjacent light emitting elements PX (a first light emitting element PX and a second light emitting element PX), a separation distance between the first lens 61 of the first light emitting element PX and the first lens 61 of the second light emitting element PX may be 0.25 μm or less. Furthermore, a separation distance between the second lens 91 of the first light emitting element PX and the second lens 91 of the second light emitting element PX may be 0.1 μm or less. By shortening the separation distance between the lenses as described above, the improvement in light extraction efficiency can be realized.

### 1-3. Comparative Example of Light Emitting Element

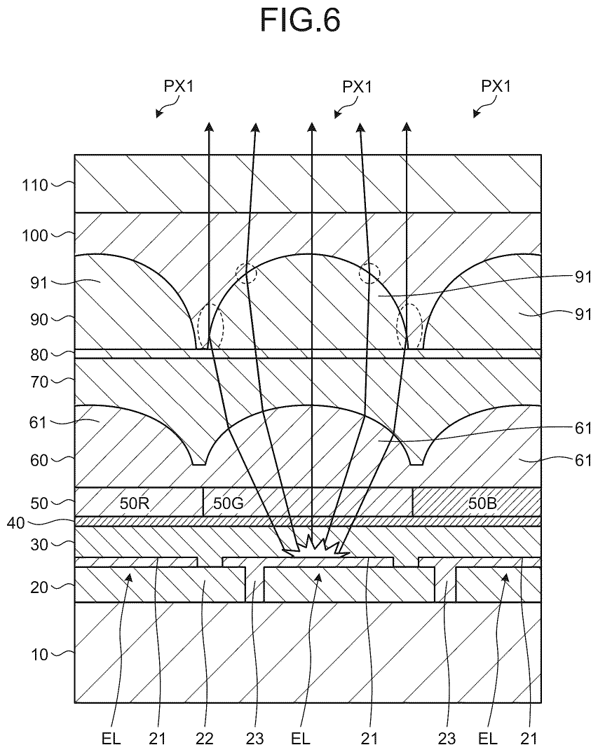

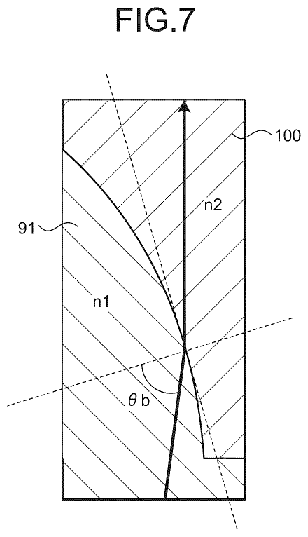

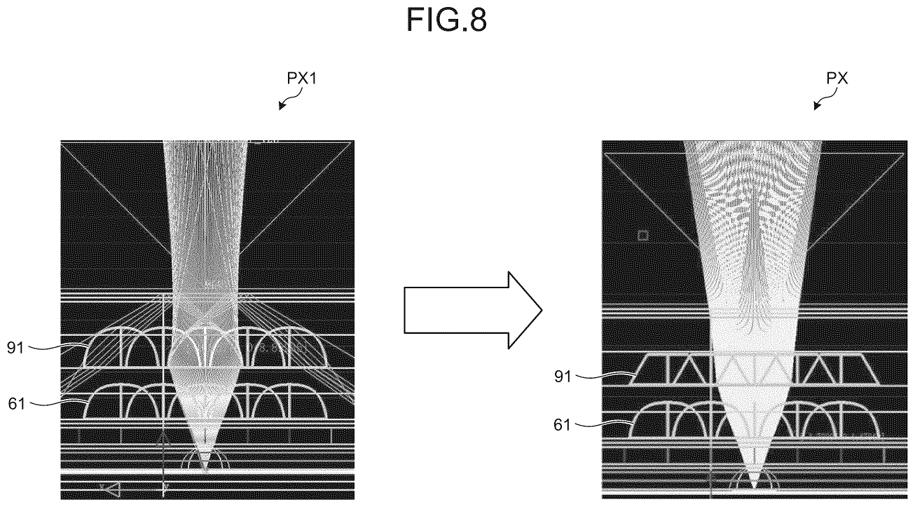

A comparative example of the light emitting element PX according to the embodiment will be described with reference to FIGS. 6 to 8. FIG. 6 is a diagram illustrating a schematic configuration of the comparative example of the light emitting element PX according to the embodiment. FIG. 7 is a diagram for explaining total reflection (critical angle) of a comparative example of the second lens 91 according to the embodiment. FIG. 8 is a diagram for explaining a comparison result (simulation result of light extraction) according to the embodiment.

As illustrated in FIG. 6, in the light emitting element PX1 of the comparative example, the shape of the first lens 61 and the shape of the second lens 91 are the same and are the same hemispherical shape. The other structures are basically similar to those of the light emitting element PX according to the embodiment. In such a configuration, total reflection occurs according to the hemispherical shape of the second lens 91 to be a spherical lens. For example, total reflection occurs near both edges (see elliptical dotted lines in FIG. 6) of the second lens 91 having a hemispherical shape. In addition, there is a possibility that light is excessively collected near the front (see circular dotted lines in FIG. 6) of the second lens 91 having a hemispherical shape. Note that it is possible to control total reflection by adjusting the lens shape, but it is difficult to control the total reflection by a reflow process at the time of forming the second lens 91 having a hemispherical shape.

Here, as illustrated in FIG. 7, when the refractive index of the second lens 91 is n1 and the refractive index of the sealing layer 100 is n2 similarly to FIG. 4, the refractive index n2 of the sealing layer 100 is lower than the refractive index n1 of the second lens 91 (n2<n1). A critical angle θb is obtained from a relational expression of θb=arcsin (n2/n1). For example, n1 (refractive index of incident source) is 1.56, and n2 (refractive index of incident destination) is 1.36. However, since the shape of the second lens 91 is a hemispherical shape, θb=63 deg. The numerical value of Ob is larger than θa=54 deg (see FIG. 4) in a case where the shape of the second lens 91 is a frustum shape. That is, it can be seen that in a case where the shape of the second lens 91 is a hemispherical shape, more light is totally reflected by the second lens 91 than in a case where the shape of the second lens 91 is a frustum shape.

For example, in a single lens structure including only one first lens 61 having a hemispherical shape, light extraction in the front direction is insufficient. Therefore, as in the comparative example, when the double lens structure (see FIG. 6) of the first lens 61 having a hemispherical shape and the second lens 91 having a hemispherical shape is adopted as illustrated in FIG. 8, light extraction changes to the front direction, but total reflection occurs at the lens edges (both edges). Therefore, as illustrated in FIG. 8, when the double lens structure (see FIG. 3) of the first lens 61 having a hemispherical shape and the second lens 91 having a frustum shape is adopted, it is possible to suppress a total reflection component at the lens edges, so that the light extraction efficiency in the front direction can be improved.

As described above, according to the present embodiment, by adopting the double lens structure of the first lens 61 having a hemispherical shape and the second lens 91 having a frustum shape, light loss at the second lens 91 in the second stage can be suppressed, and light can be extracted further in the front direction, so that the light extraction efficiency (light emission efficiency) in the front direction can be improved. As a result, higher luminance and lower power consumption can be realized. For example, an effect can be expected in applications to augmented reality (AR)/virtual reality (VR) glasses and the like in which front luminance is emphasized rather than a luminance viewing angle.

### 1-4. Modifications of Light Emitting Element

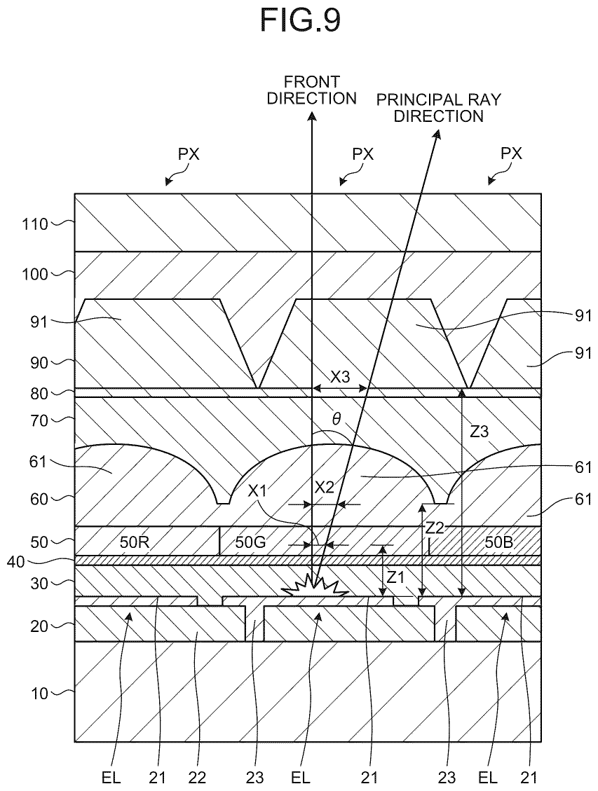

Modifications 1 to 3 of the light emitting element according to the embodiment will be described with reference to FIGS. 9 to 11. FIGS. 9 to 11 are diagrams for respectively explaining modifications (Modifications 1 to 3) of the light emitting element PX according to the embodiment.

As illustrated in FIG. 9, in Modification 1, the color filter layer 50 is shifted rightward in FIG. 9 by a distance X1 (X1=Z1× tan θ). For example, a normal line (central axis) passing through the center of the color filter 50G is shifted rightward in FIG. 9 by the distance X1 with respect to a normal line (central axis) passing through the center (for example, the center of the anode electrode 21) of the corresponding light emitting unit EL. The same applies to the other color filters 50R and 50B.

The first lens layer 60 is shifted rightward in FIG. 9 by a distance X2 (X2=Z2×tan θ). For example, a normal line (central axis) passing through the center of the first lens 61 is shifted rightward in FIG. 9 by the distance X2 with respect to a normal line passing through the center of the corresponding light emitting unit EL. The same applies to the other first lenses 61.

The second lens layer 90 is shifted rightward in FIG. 9 by a distance X3 (X3=Z3×tan θ). For example, a normal line (central axis) passing through the center of the second lens 91 is shifted rightward in FIG. 9 by the distance X3 with respect to a normal line passing through the center of the corresponding light emitting unit EL. The same applies to the other second lenses 91.

According to Modification 1, a principal ray direction of the light emitting element PX can be controlled by shifting the color filter layer 50, the first lens layer 60, the second lens layer 90, and the like of the light emitting element PX, so that a light distribution characteristic can be adjusted. For example, a principal ray of each light emitting element PX in a region on the panel outer peripheral side of the display device 1 can be controlled to spread from the panel outer peripheral side, or can be controlled to be collected to the panel center side.

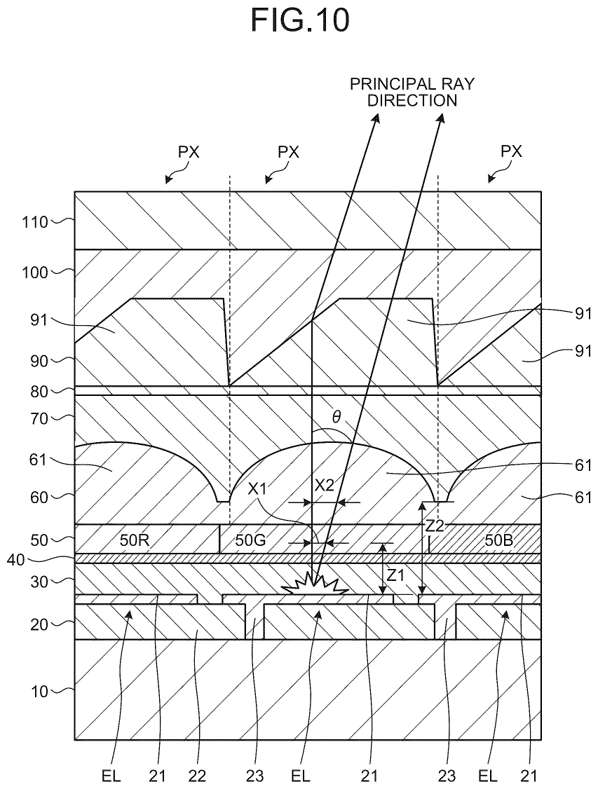

As illustrated in FIG. 10, in Modification 2, the color filter layer 50 is shifted rightward in FIG. 10 by the distance X1 (X1=Z1×tan θ), similarly to Modification 1 (see FIG. 9). In addition, the first lens layer 60 is also shifted rightward in FIG. 10 by the distance X2 (X2=Z2×tan θ), similarly to Modification 1 (see FIG. 9).

The second lens layer 90 is shifted rightward in FIG. 10 by the distance X2, similarly to the first lens layer 60. For example, the normal line passing through the center of the second lens 91 is shifted rightward in FIG. 10 by the distance X2 with respect to the normal line passing through the center of the corresponding light emitting unit EL. The same applies to the other second lenses 91.

Two base angles (for example, right and left tapered shapes in a longitudinal cross section) of the second lens 91 in the longitudinal cross section of the second lens 91 are formed in different frustum shapes. The longitudinal cross section is a cross section parallel to a height direction of the second lens 91. The two base angles of the second lens 91 in the longitudinal cross section are adjusted according to the separation distance between the light emitting element PX including the second lens 91 and the center of the display device 1 (the center of the display panel). As a result, the degree of inclination of the oblique side of the second lens 91 can be adjusted, so that the light distribution characteristic can be controlled without shifting the second lens layer 90 in the second stage as in Modification 1.

Note that in Modification 2, the two base angles of the second lens 91 having a frustum shape in the longitudinal cross section are adjusted according to the separation distance between the light emitting element PX and the center of the display device 1, but the present invention is not limited thereto. For example, the display device 1 (display panel) may be divided into a plurality of regions, and the two base angles of the second lens 91 having a frustum shape in the longitudinal cross section may be adjusted for each region. As the region division of the display device 1, for example, the display device 1 may be divided into a plurality of regions arranged in a longitudinal direction or a lateral direction of the display device 1, or into a plurality of regions arranged in both the longitudinal direction and the lateral direction of the display device 1.

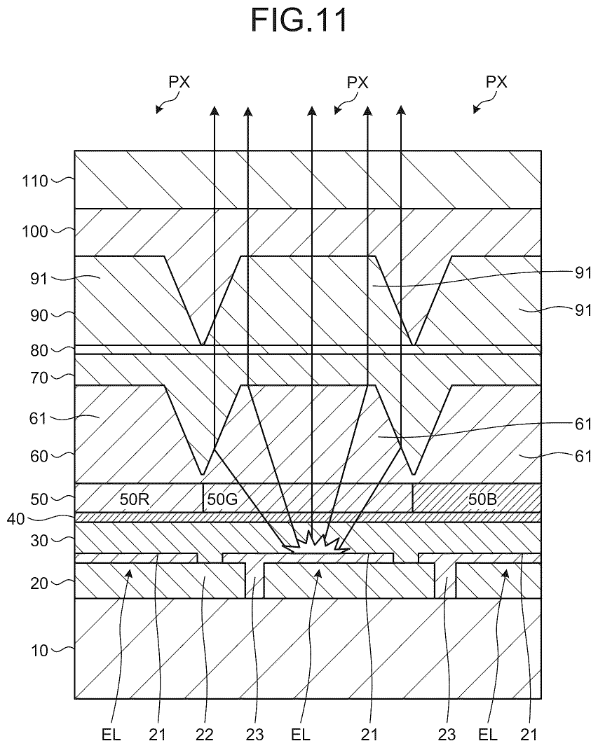

As illustrated in FIG. 11, in Modification 3, the shape of the first lens 61 and the shape of the second lens 91 are the same and are the same frustum shape. For example, the shape of the first lens 61 and the shape of the second lens 91 are the same truncated quadrangular pyramid shape.

Note that in Modification 3, the shape of the first lens 61 and the shape of the second lens 91 are the same frustum shape, but are not limited thereto, and may be different frustum shapes. For example, the shape of the first lens 61 may be a truncated cone shape, and the shape of the second lens 91 may be a truncated pyramid shape. In addition, the shape of the first lens 61 may be a truncated quadrangular pyramid shape, and the shape of the second lens 91 may be a truncated octagonal pyramid shape. The number of angles of the frustum shape of the second lens 91 may be the same as the number of angles of the frustum shape of the first lens 61, and may be larger or smaller than the number of angles of the frustum shape of the first lens 61 in some cases. In addition, the height or the base angle of the second lens 91 may be the same as the height or the base angle of the first lens 61, and may be larger or smaller than the height or the base angle of the first lens 61 in some cases.

In addition, the first lens 61 and the second lens 91 are stacked in two stages of two layers, but may be stacked in three stages of three layers, or more. The respective shapes of the lenses in the three or more stages may be the same or different, but the shape of at least one lens is a frustum shape.

In addition, the planar shape (upper surface shape or lower surface shape in plan view) of the second lens 91 may be formed in the same shape as the planar shape (outer shape) of the anode electrode 21. Since the planar shape of the light emitting surface of the light emitting unit EL generally follows the planar shape of the anode electrode 21, the planar outer shape of the second lens 91 may be matched with the planar outer shape of the anode electrode 21.

### 1-5. Actions and Effects

As described above, the light emitting element PX according to the embodiment includes the light emitting unit EL that outputs light from the light emitting region, the first lens 61 having a hemispherical shape or a frustum shape and provided above the light emitting region of the light emitting unit EL, and the second lens 91 having a frustum shape and provided above the first lens 61. As a result, total reflection at the second lens 91 can be suppressed, so that improvement in light extraction efficiency (light emission efficiency) in the front direction, that is, improvement in light extraction efficiency can be realized.

In addition, the shape of the second lens 91 may be a truncated pyramid. As a result, the improvement in light extraction efficiency can be reliably realized.

In addition, the shape of the second lens 91 may be a truncated cone. As a result, the improvement in light extraction efficiency can be reliably realized.

In addition, the shape of the first lens 61 may be a hemispherical shape and may be different from the shape of the second lens 91. Even in this case, the improvement in light extraction efficiency can be realized.

In addition, the shape of the first lens 61 may be a frustum shape and may be the same as the shape of the second lens 91. As a result, the improvement in light extraction efficiency can be reliably realized.

In addition, the shape of the first lens 61 may be a frustum shape and may be different from the shape of the second lens 91. As a result, the improvement in light extraction efficiency can be reliably realized.

In addition, the light emitting element PX may further include the filling layer 70 provided between the first lens 61 and the second lens 91. As a result, an appropriate stacked structure of the first lens 61 and the second lens 91 can be realized, so that the improvement in light extraction efficiency can be reliably realized.

In addition, the refractive index of the filling layer 70 may be lower than the refractive index of the first lens 61. As a result, the difference between the refractive index of the filling layer 70 and the refractive index of the first lens 61 can be increased, and the light extraction efficiency in the front direction can be improved.

In addition, the light emitting element PX may further include the planarization layer 80 (for example, an acrylic resin or the like) provided on the first lens 61 side of the second lens 91. As a result, peeling of the second lens 91 can be suppressed, so that the improvement in light extraction efficiency can be reliably realized.

In addition, the base angle of the second lens 91 may be set according to the height of the first lens 61. As a result, total reflection of the second lens 91 can be controlled, so that the improvement in light extraction efficiency can be reliably realized.

In addition, the base angle of the second lens 91 may be set to decrease as the height of the first lens 61 increases. As a result, the improvement in light extraction efficiency can be reliably realized according to the height of the first lens 61.

In addition, the base angle of the second lens 91 may be set to increase as the height of the first lens 61 decreases. As a result, the improvement in light extraction efficiency can be reliably realized according to the height of the first lens 61.

In addition, the base area of the second lens 91 may be larger than the base area of the first lens 61. As a result, the improvement in light extraction efficiency can be reliably realized.

In addition, the central axis that is the normal line passing through the center of the second lens 91 may be shifted with respect to the central axis that is the normal line passing through the center of the light emitting unit EL. As a result, the principal ray direction of the light emitting element PX can be controlled, so that light extraction efficiency in a desired direction can be improved.

In addition, the central axis that is the normal line passing through the center of the first lens 61 may be shifted in the same direction as the central axis of the second lens 91 with respect to the central axis that is the normal line passing through the center of the light emitting unit EL. As a result, the light extraction efficiency in the desired direction can be reliably improved.

In addition, the two base angles of the second lens 91 in the longitudinal cross section may be different. As a result, it is possible to control the principal ray direction of the light emitting element PX by adjusting the degree of inclination of the two oblique sides of the second lens 91 in the longitudinal cross section, so that the light extraction efficiency in the desired direction can be improved.

In addition, in the plurality of light emitting elements PX, the separation distance between the first lens 61 of the first light emitting element PX and the first lens 61 of the second light emitting element PX adjacent to the first light emitting element PX may be 0.25 μm or less. As a result, the improvement in light extraction efficiency can be reliably realized.

In addition, in the plurality of light emitting elements PX, the separation distance between the second lens 91 of the first light emitting element PX and the second lens 91 of the second light emitting element PX adjacent to the first light emitting element PX may be 0.1 μm or less. As a result, the improvement in light extraction efficiency can be reliably realized.

### 2. Other Embodiments

The processing according to the above-described embodiments (or modifications) may be performed in various different modes (modifications) other than the above-described embodiments. For example, the processing procedure, the specific name, and the information including various data and parameters illustrated in the above-described document or the drawings can be arbitrarily changed unless otherwise specified. For example, the various information illustrated in the drawings are not limited to the illustrated information. In addition, the above-described embodiments (or modifications) can be appropriately combined within a range that does not contradict the processing contents. Note that the effects described in the present specification are merely illustrative or exemplary, and are not limited.

For example, the color filter may be configured to include a coloring material and/or fine particles constituting quantum dots. In addition, the color filter may be configured using a well-known resist material to which a desired coloring material or the like is added. As the coloring material, well-known pigments and dyes can be used. In addition, the fine particles constituting the quantum dots are not particularly limited, and for example, light emitting semiconductor nanoparticles may be used. The color filter including the coloring material performs color display by transmitting light in a target wavelength range among the light from the light emitting element PX. In addition, the color filter including the fine particles constituting the quantum dots performs color display by performing wavelength conversion of the light from the light emitting element PX.

In addition, as a color filter array (color pattern), for example, various patterns such as a Bayer array (for example, RGBG, GRGB, RGGB, and the like), an RGB array, an RGB stripe array, and an RGB mosaic array can be used, and color filters of various complementary colors can be used in addition to the color filters of primary colors of RGB. In addition, the stacking position of each color filter (for example, the color filter layer 50) is not particularly limited as long as it is on the optical path of the light output from the light emitting unit EL.

In addition, as a material constituting the light emitting element PX, a suitable material is appropriately selected from transparent organic materials and inorganic materials and used. The light emitting element PX is obtained, for example, by forming a resist on a transparent material layer and performing etching.

In addition, as the light emitting unit EL, an LED element, a semiconductor laser element, or the like can be used in addition to the organic electroluminescence element. These are configured using well-known materials and methods. In particular, it is preferable to have a configuration including the organic electroluminescence element as the light emitting unit EL from the viewpoint of constituting a planar display device.

In addition, the light emitting element PX may have a resonator structure that causes light to resonate. Since the light emitting element PX has the resonator structure, the light emission color of the light emitting element PX can be set to a predetermined display color, so that a color filter is basically unnecessary. However, in order to further improve the color purity of light having a long wavelength, the display device 1 may further include a color filter corresponding to the light emitting element PX for red display. Alternatively, in order to improve the color purity of the display colors in general, the display device 1 may further include color filters corresponding to the light emitting element PX for red display, the light emitting element PX for green display, and the light emitting element PX for blue display.

In addition, as a constituent material of the substrate 10, a semiconductor material, a glass material, a plastic material, or the like can be used. In a case where the drive circuit A1 includes a transistor formed in a semiconductor substrate, for example, a well region may be provided in a semiconductor substrate made of silicon, and a transistor may be formed in the well. On the other hand, when the drive circuit A1 includes a thin film transistor or the like, a semiconductor thin film can be formed on a substrate made of a glass material or a plastic material to form the drive circuit A1. Various wirings may have known configurations and structures.

In addition, in the display device 1, the configuration of the drive circuit A1 or the like that controls light emission of the light emitting element PX is not particularly limited. The configuration of the transistor constituting the drive circuit A1 is not particularly limited, and may be, for example, a p-channel field effect transistor or an n-channel field effect transistor.

In addition, in the display device 1, the light emitting element PX is of a so-called top emission type. For example, the light emitting element PX including an organic electroluminescence element is configured by sandwiching an organic layer including a hole transport layer, a light emitting layer, an electron transport layer, and the like between a first electrode and a second electrode. When a common cathode is used, the first electrode is an anode electrode, and the second electrode is a cathode electrode. The first electrode is provided for each light emitting element PX on the substrate 10.

The first electrode may be formed of, for example, a simple substance or an alloy of a metal having a high work function, such as platinum (Pt), gold (Au), silver (Ag), chromium (Cr), tungsten (W), nickel (Ni), copper (Cu), iron (Fe), cobalt (Co), or tantalum (Ta). In addition, the first electrode may be formed as a stacked electrode in which a transparent conductive material such as indium zinc oxide (IZO) or indium tin oxide (ITO) is stacked on a dielectric multilayer film or a thin film having high light reflectivity such as aluminum.

The second electrode may be formed of, for example, a metal or an alloy having a low work function, such as aluminum (Al), silver (Ag), magnesium (Mg), calcium (Ca), sodium (Na), strontium (Sr), an alloy of an alkali metal and silver, an alloy of an alkaline earth metal and silver, an alloy of magnesium and calcium, or an alloy of aluminum and lithium. In addition, the second electrode may be formed of a transparent conductive material such as indium zinc oxide (IZO) or indium tin oxide (ITO), or may be formed as a stacked electrode of a layer made of the material having a low work function described above and a layer made of a transparent conductive material such as indium zinc oxide (IZO) or indium tin oxide (ITO).

In addition, the organic layer 30 is formed by stacking a plurality of material layers, and is provided as a common continuous film on the entire surface including the first electrode. The organic layer 30 emits light when a voltage is applied between the first electrode and the second electrode. The organic layer 30 has, for example, a structure in which a hole injection layer, a hole transport layer, a light emitting layer, an electron transport layer, and an electron injection layer are stacked in this order from the first electrode side. A hole transport material, a hole transport material, an electron transport material, and an organic light emitting material constituting the organic layer 30 are not limited, and well-known materials can be used.

In addition, the organic layer 30 may include a structure in which a plurality of light emitting layers are stacked. For example, the light emitting element PX that emits white light can be configured by stacking light emitting layers for red light emission, blue light emission, and green light emission, or by stacking light emitting layers for blue light emission and yellow light emission. In addition, a light emitting layer may be applied to each light emitting element PX according to a color to be displayed.

In addition, the pixel may include one light emitting element PX or may include a plurality of light emitting elements PX. For example, the pixel may include a plurality of sub-pixels (light emitting elements PX). Specifically, a configuration including three types of sub-pixels of a red display sub-pixel, a green display sub-pixel, and a blue display sub-pixel can be used as one pixel. In addition, as one pixel, one set (for example, one set including a sub-pixel that emits white light to improve luminance, one set including a sub-pixel that emits complementary color light to expand a color reproduction range, one set including a sub-pixel that emits yellow light to expand a color reproduction range, and one set including sub-pixels that emit yellow and cyan light to expand a color reproduction range) obtained by further adding one or a plurality of types of sub-pixels to the three types of sub-pixels can be used.

In addition, there may be a partition wall portion that partitions adjacent light emitting elements PX, and the partition wall portion may be formed using a material appropriately selected from known inorganic materials and organic materials. For example, the partition wall portion may be formed by a combination of a well-known film forming method such as a physical vapor deposition method (PVD method) exemplified by a vacuum vapor deposition method or a sputtering method or various chemical vapor deposition methods (CVD methods) and a well-known patterning method such as an etching method or a lift-off method.

In addition, as the value of the pixel (pixel) of the display device 1, in addition to VGA (640, 480), S-VGA (800, 600), XGA (1024, 768), APRC (1152, 900), S-XGA (1280, 1024), U-XGA (1600, 1200), HD-TV (1920, 1080), and Q-XGA (2048, 1536), some image display resolutions such as (1920, 1035), (720, 480), and (1280, 960) can be exemplified, but the values are not limited thereto.

### 3. Example of Resonator Structure

The pixel that is the light emitting element PX used in the display device 1 according to the present disclosure described above may have a resonator structure that causes light generated in the light emitting unit to resonate. Hereinafter, a resonator structure applied to each embodiment will be described with reference to the drawings. Note that, any of R, G, and B may be assigned to a reference numeral as necessary for distinction (the same applies to the drawings).

### (Resonator Structure: First Example)

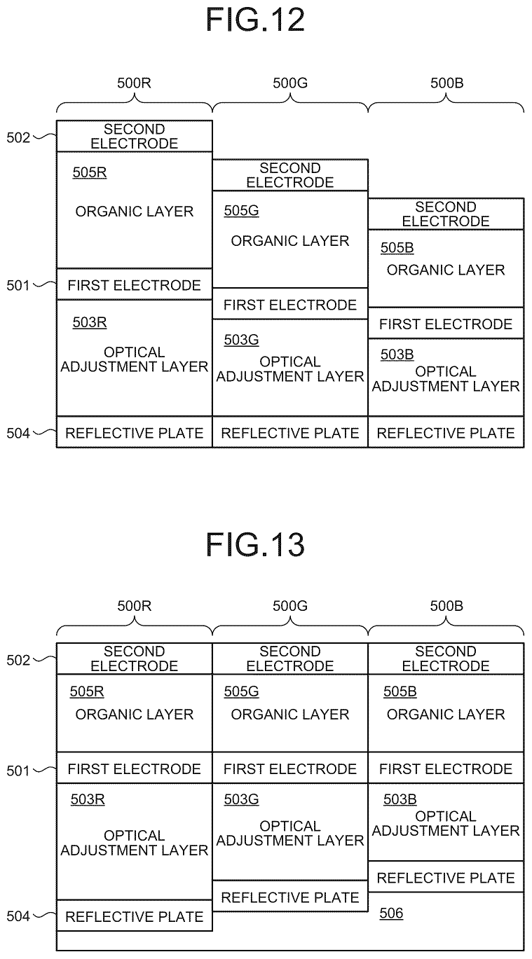

FIG. 12 is a schematic cross-sectional diagram for describing a first example of the resonator structure.

In the first example, first electrodes 501 in respective light emitting elements 500 are formed to have a common film thickness. The same applies to second electrodes 502. For example, the light emitting elements 500 correspond to the light emitting elements PX described above, the first electrodes 501 correspond to the anode electrodes 21 described above, and the second electrodes 502 correspond to the cathode layer 40 functioning as the cathode electrode described above.

A reflection plate 504 is disposed below each first electrode 501 of the light emitting element 500 with an optical adjustment layer 503 interposed between them. A resonator structure that resonates light generated by an organic layer 505 is formed between the reflection plate 504 and the second electrode 502. For example, the organic layer 505 corresponds to the above-described organic layer 30.

The reflection plates 504 in the respective light emitting elements 500 are formed to have a common film thickness. The film thickness of the optical adjustment layer 503 varies depending on the color to be displayed by the pixel. Since the optical adjustment layers 503R, 503G, and 503B have different film thicknesses, it is possible to set an optical distance at which resonance that is optimum for a wavelength of light according to the color to be displayed occurs.

In the example illustrated in FIG. 12, upper surfaces of the reflection plates 504 in light emitting elements 500R, 500G, and 500B are arranged so as to be aligned with each other. As described above, since the film thickness of the optical adjustment layer 503 varies depending on the color to be displayed by the pixel, the position of the upper surface of the second electrode 502 varies depending on the type of the light emitting element 500 (the light emitting elements 500R, 500G, and 500B).

The reflection plate 504 can be formed using, for example, a metal such as aluminum (Al), silver (Ag), or copper (Cu), or an alloy containing these as a main component.

The optical adjustment layer 503 can be made of an inorganic insulating material such as silicon nitride (SiNx), silicon oxide (SiOx), or silicon oxynitride (SiOxNy), or an organic resin material such as an acrylic resin or a polyimide resin. The optical adjustment layer 503 may be a single layer or a laminated film of multiple materials. Further, the number of laminated layers may vary depending on the type of each light emitting element 500.

The first electrode 501 can be formed using a transparent conductive material such as indium tin oxide (ITO), indium zinc oxide (IZO), or zinc oxide (ZnO).

The second electrode 502 needs to function as a semi-transmissive reflection film. The second electrode 502 can be formed using magnesium (Mg), silver (Ag), a magnesium-silver alloy (MgAg) containing these as a main component, an alloy containing an alkali metal or an alkaline earth metal, and the like.

### (Resonator Structure: Second Example)

FIG. 13 is a schematic cross-sectional diagram for describing a second example of the resonator structure.

Also in the second example, the first electrodes 501 and the second electrodes 502 in the respective light emitting elements 500 are formed to have a common film thickness.

Also in the second example, the reflection plate 504 is disposed below each first electrode 501 of the light emitting element 500 with the optical adjustment layer 503 interposed between them. A resonator structure that resonates light generated by an organic layer 505 is formed between the reflection plate 504 and the second electrode 502. As in the first example, the reflection plates 504 in the respective light emitting elements 500 are formed to have a common film thickness, and the film thickness of the optical adjustment layer 503 varies depending on the color to be displayed by the pixel.

In the first example illustrated in FIG. 12, the upper surfaces of the reflection plates 504 in the light emitting elements 500R, 500G, and 500B are arranged so as to be aligned with each other, and the position of the upper surface of the second electrode 502 varies depending on the type of the light emitting element 500.

On the other hand, in the second example illustrated in FIG. 13, the upper surfaces of the second electrodes 502 in the light emitting elements 500R, 500G, and 500B are arranged so as to be aligned with each other. In order to align the upper surfaces of the second electrodes 502, the upper surfaces of the reflection plates 504 in the light emitting elements 500R, 500G, and 500B are arranged so as to vary depending on the type of the light emitting element 500. Thus, lower surfaces of the reflection plates 504 (in other words, an upper surface of a foundation 506 illustrated in FIG. 13) have a stair shape according to the type of the light emitting element 500.

Materials and the like constituting the reflection plates 504, the optical adjustment layers 503, the first electrodes 501, and the second electrodes 502 are similar to those described in the first example, and thus their description is omitted.

### (Resonator Structure: Third Example)

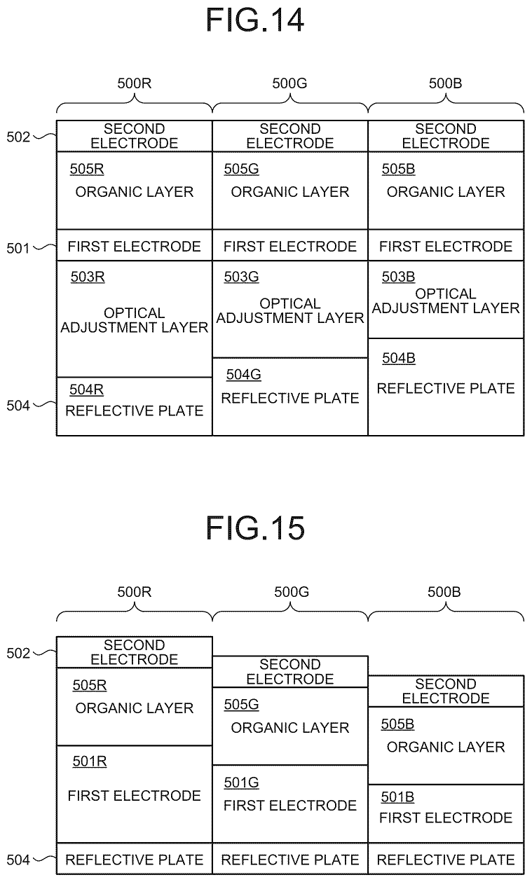

FIG. 14 is a schematic cross-sectional diagram for describing a third example of the resonator structure.

Also in the third example, the first electrodes 501 and the second electrodes 502 in the respective light emitting elements 500 are formed to have a common film thickness.

Also in the third example, the reflection plate 504 is disposed below each first electrode 501 of the light emitting element 500 with the optical adjustment layer 503 interposed between them. A resonator structure that resonates light generated by an organic layer 505 is formed between the reflection plate 504 and the second electrode 502. As in the first example and the second example, the film thickness of the optical adjustment layer 503 varies depending on the color to be displayed by the pixel. As in the second example, the upper surfaces of the second electrodes 502 in the light emitting elements 500R, 500G, and 500B are positioned so as to be aligned with each other.

In the second example illustrated in FIG. 13, in order to align the upper surfaces of the second electrodes 502, the lower surfaces of the reflection plates 504 have a stair shape according to the type of the light emitting element 500.

On the other hand, in the third example illustrated in FIG. 14, the film thickness of the reflection plate 504 is set to vary depending on the type of the light emitting element 500. More specifically, the film thickness is set so that the lower surfaces of the reflection plates 504R, 504G, and 504B are aligned with each other.

Materials and the like constituting the reflection plates 504, the optical adjustment layers 503, the first electrodes 501, and the second electrodes 502 are similar to those described in the first example, and thus their description is omitted.

### (Resonator Structure: Fourth Example)

FIG. 15 is a schematic cross-sectional diagram for describing a fourth example of the resonator structure.

In the first example illustrated in FIG. 12, the first electrodes 501 and the second electrodes 502 in the respective light emitting elements 500 are formed to have a common film thickness. The reflection plate 504 is disposed below each first electrode 501 of the light emitting element 500 with the optical adjustment layer 503 interposed between them.

On the other hand, in the fourth example illustrated in FIG. 15, the optical adjustment layer 503 is omitted, and the film thickness of the first electrode 501 is set to vary depending on the type of the light emitting element 500.

The reflection plates 504 in the respective light emitting elements 500 are formed to have a common film thickness. The film thickness of the first electrode 501 varies depending on the color to be displayed by the pixel. Since the first electrodes 501R, 501G, and 501B have different film thicknesses, it is possible to set an optical distance at which resonance that is optimum for a wavelength of light according to the color to be displayed occurs.

Materials and the like constituting the reflection plates 504, the optical adjustment layers 503, the first electrodes 501, and the second electrodes 502 are similar to those described in the first example, and thus their description is omitted.

### (Resonator Structure: Fifth Example)

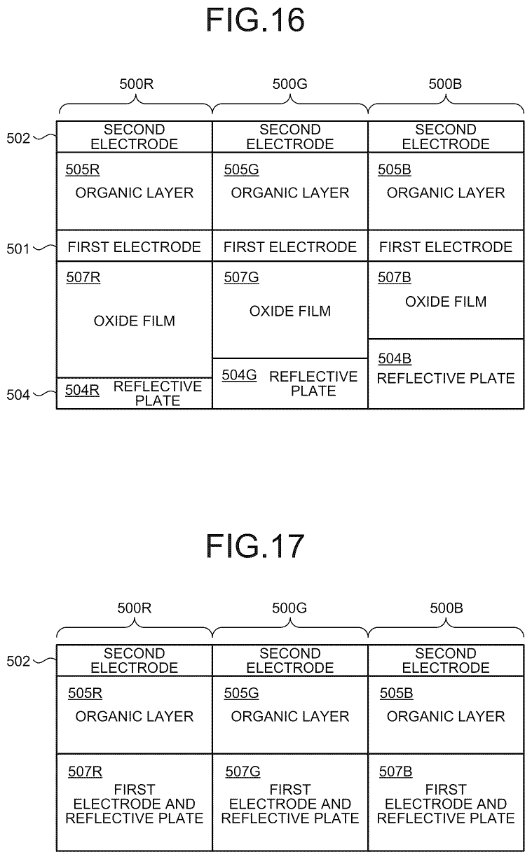

FIG. 16 is a schematic cross-sectional diagram for describing a fifth example of the resonator structure.

In the first example illustrated in FIG. 12, the first electrodes 501 and the second electrodes 502 in the respective light emitting elements 500 are formed to have a common film thickness. The reflection plate 504 is disposed below each first electrode 501 of the light emitting element 500 with the optical adjustment layer 503 interposed between them.

On the other hand, in the fifth example illustrated in FIG. 16, the optical adjustment layer 503 is omitted, and instead, an oxide film 507 is formed on the surface of each reflection plate 504. The film thickness of the oxide film 507 is set to vary depending on the type of the light emitting element 500.

The film thickness of the oxide film 507 varies depending on the color to be displayed by the pixel. Since the oxide films 507R, 507G, and 507B have different film thicknesses, it is possible to set an optical distance at which resonance that is optimum for a wavelength of light according to the color to be displayed occurs.

The oxide film 507 is a film obtained by oxidizing the surface of the reflection plate 504, and is made of, for example, aluminum oxide, tantalum oxide, titanium oxide, magnesium oxide, zirconium oxide, or the like. The oxide film 507 functions as an insulating film for adjusting a light path length (optical distance) between the reflection plate 504 and the second electrode 502.

The oxide films 507 having different film thicknesses depending on the type of the light emitting element 500 can be formed, for example, as follows.

First, an electrolytic solution is filled in a container, and a substrate on which the reflection plates 504 are formed is immersed in the electrolytic solution. Further, electrodes are disposed so as to face the reflection plates 504.

Then, a positive voltage is applied to the reflection plates 504 with the electrodes used as a reference, and the reflection plates 504 are anodized. The film thickness of the oxide film due to the anodization is proportional to the voltage value with respect to the electrode. Thus, the anodization is performed while voltages corresponding to the type of the light emitting element 500 are applied to the respective reflection plates 504R, 504G, and 504B. As a result, the oxide films 507 having different film thicknesses can be collectively formed.

Materials and the like constituting the reflection plates 504, the first electrodes 501, and the second electrodes 502 are similar to those described in the first example, and thus their description is omitted.

### (Resonator Structure: Sixth Example)

FIG. 17 is a schematic cross-sectional diagram for describing a sixth example of the resonator structure.

In the sixth example, the light emitting element 500 is configured by laminating the first electrode 501, the organic layer 505, and the second electrode 502. However, in the sixth example, the first electrode 501 is formed to function as both the electrode and the reflection plate. The first electrode (also serving as the reflection plate) 501 is made of a material having an optical constant selected according to the type of the light emitting element 500. Since the phase shift by the first electrode (also serving as the reflection plate) 501 varies, it is possible to set an optical distance at which resonance that is optimum for a wavelength of light according to the color to be displayed occurs.

The first electrode (also serving as the reflection plate) 501 can be made of a single metal such as aluminum (Al), silver (Ag), gold (Au), or copper (Cu), or an alloy containing these as a main component. For example, the first electrode (also serving as the reflection plate) 501R of the light emitting element 500R may be made of copper (Cu), and the first electrode (also serving as the reflection plate) 501G of the light emitting element 500G and the first electrode (also serving as the reflection plate) 501B of the light emitting element 500B may be made of aluminum.

Materials and the like constituting the second electrodes 502 are similar to those described in the first example, and thus their description is omitted.

### (Resonator Structure: Seventh Example)

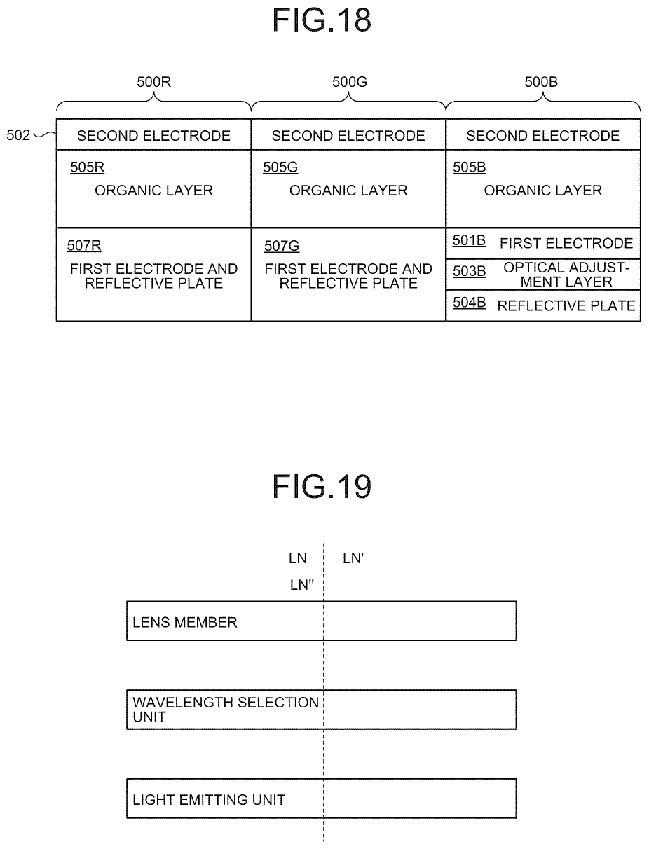

FIG. 18 is a schematic cross-sectional diagram for describing a seventh example of the resonator structure.

In the seventh example, basically, the sixth example is applied to the light emitting elements 500R and 500G, and the first example is applied to the light emitting element 500B. Also in this configuration, it is possible to set an optical distance at which resonance that is optimum for a wavelength of light according to the color to be displayed occurs.

The first electrodes (also serving as the reflection plates) 501R and 501G used in the light emitting elements 500R and 500G can be made of a single metal such as aluminum (Al), silver (Ag), gold (Au), or copper (Cu), or an alloy containing these as a main component.

Materials and the like constituting the reflection plate 504B, the optical adjustment layer 503B, and the first electrode 501B used for the light emitting element 500B are similar to those described in the first example, and thus their description is omitted.

### 4. Example of Shift Structure

The pixel that is the light emitting element PX used in the display device 1 according to the present disclosure described above may have a shift structure that shifts any one of the light emitting unit (for example, the light emitting unit EL), a lens member (for example, the first lens 61, the second lens 91), and a wavelength selection unit (for example, the color filter layer 50). Hereinafter, the relationship among a normal line LN passing through the center of the light emitting unit, a normal line LN′ passing through the center of the lens member, and a normal line LN″ passing through the center of the wavelength selection unit will be described with reference to FIGS. 19 to 25. FIGS. 19 to 25 are conceptual diagrams for describing first to seventh examples of the shift structure, respectively.

Note that, the size of the wavelength selection unit may be appropriately changed so as to correspond to the light emitted from the light emitting element, or in a case where a light absorbing layer (black matrix layer) is provided between the wavelength selection units of the adjacent light emitting elements, the size of the light absorbing layer may be appropriately changed so as to correspond to the light emitted from the light emitting element. In addition, the size of the wavelength selection unit may be appropriately changed according to the distance (offset amount) do between the normal line passing through the center of the light emitting unit and the normal line passing through the center of the color filter layer CF. The planar shape of the wavelength selection unit may be the same as, similar to, or different from the planar shape of the lens member.

### (Shift Structure: First Example)

As illustrated in FIG. 19, the normal line LN passing through the center of the light emitting unit, the normal line LN″ passing through the center of the wavelength selection unit, and the normal line LN′ passing through the center of the lens member coincide with each other. That is, D₀≠d₀=0.

### (Shift Structure: Second Example)

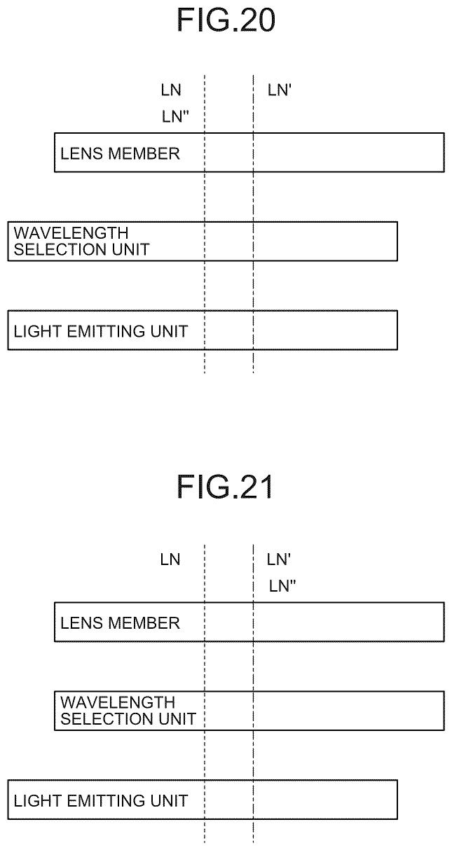

As illustrated in FIG. 20, the normal line LN passing through the center of the light emitting unit coincides with the normal line LN″ passing through the center of the wavelength selection unit, but the normal line LN passing through the center of the light emitting unit and the normal line LN″ passing through the center of the wavelength selection unit do not coincide with the normal line LN′ passing through the center of the lens member. That is, D₀≠d₀=0.

### (Shift Structure: Third Example)

As illustrated in FIG. 21, the normal line LN passing through the center of the light emitting unit does not coincide with the normal line LN″ passing through the center of the wavelength selection unit and the normal line LN′ passing through the center of the lens member, and the normal line LN″ passing through the center of the wavelength selection unit coincides with the normal line LN′ passing through the center of the lens member. That is, D₀=d₀>0.

### (Shift Structure: Fourth Example)

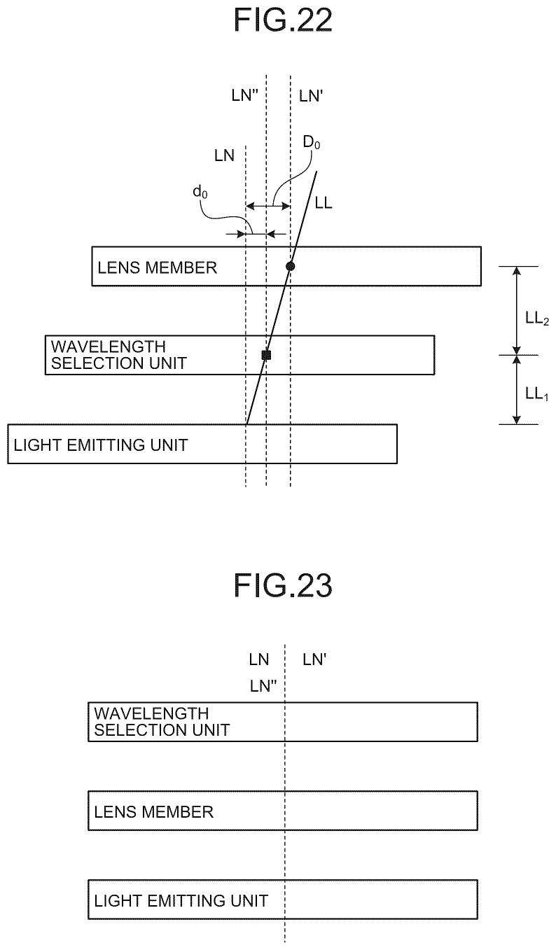

As illustrated in FIG. 22, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit (indicated by a black square in FIG. 22) is preferably located on a straight line LL that connects the center of the light emitting unit and the center of the lens member (indicated by a black circle in FIG. 22). Specifically, when a distance from the center of the light emitting unit to the center of the wavelength selection unit in the thickness direction is LL₁, and a distance from the center of the wavelength selection unit to the center of the lens member in the thickness direction is LL₂,

D₀>d₀>0

is satisfied, and considering manufacturing variations,
d₀: D₀=LL₁: (LL₁+LL₂) is preferably satisfied.

### (Shift Structure: Fifth Example)

As illustrated in FIG. 23, the normal line LN passing through the center of the light emitting unit, the normal line LN″ passing through the center of the wavelength selection unit, and the normal line LN′ passing through the center of the lens member coincide with each other. That is, D₀=d₀=0.

### (Shift Structure: Sixth Example)

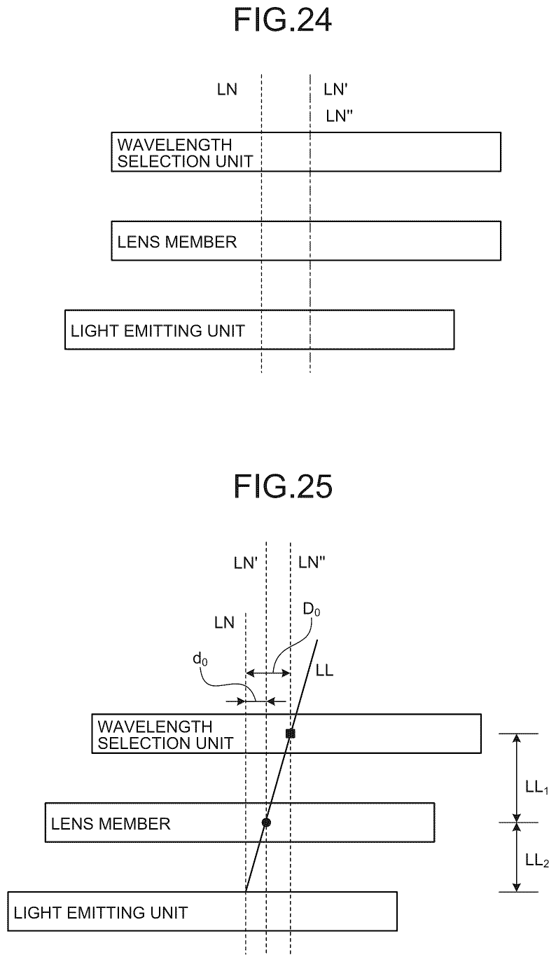

As illustrated in FIG. 24, the normal line LN passing through the center of the light emitting unit does not coincide with the normal line LN″ passing through the center of the wavelength selection unit and the normal line LN′ passing through the center of the lens member, and the normal line LN″ passing through the center of the wavelength selection unit coincides with the normal line LN′ passing through the center of the lens member. That is, D₀=d₀>0.

### (Shift Structure: Seventh Example)

As illustrated in FIG. 25, the normal line LN passing through the center of the light emitting unit may not coincide with the normal line LN″ passing through the center of the wavelength selection unit and the normal line LN′ passing through the center of the lens member, and the normal line LN′ passing through the center of the lens member may not coincide with the normal line LN passing through the center of the light emitting unit and the normal line LN″ passing through the center of the wavelength selection unit. Here, the center of the wavelength selection unit is preferably located on the straight line LL that connects the center of the light emitting unit and the center of the lens member. Specifically, when a distance from the center of the light emitting unit to the center of the wavelength selection unit in the thickness direction (indicated by a black square in FIG. 25) is LL₁, and a distance from the center of the wavelength selection unit to the center of the lens member in the thickness direction (indicated by a black circle in FIG. 25) is LL₂,

d₀>D₀>0

is satisfied, and considering manufacturing variations,
D₀: d₀=LL₂: (LL₁+LL₂) is preferably satisfied.

### 5. Application Example

The display device 1 according to the embodiment described above can be used as a display unit of an electronic apparatus in any field that displays, as an image or a video, a video signal input to the electronic apparatus or a video signal generated in the electronic apparatus. For example, the display device 1 according to the embodiment can be used as a display unit of a mobile terminal device such as a smartphone or a mobile phone, a digital still camera, a head mounted display, a see-through head mounted display, a television device, a notebook personal computer, a video camera, an electronic book, a game machine, or the like.

Note that, the display device according to the embodiment may include a module-shaped device having a sealed configuration. The display module may be provided with a circuit unit for inputting and outputting a signal and the like from the outside to a light emitting region, a flexible printed circuit (FPC), and the like.

As specific examples (application examples) of the electronic apparatus using the display device according to the embodiment, a smartphone, a digital still camera, a head mounted display, a see-through head mounted display, a television device, and a vehicle will be exemplified below. However, the specific examples exemplified here are merely an example, and the present invention is not limited to this.

### Specific Example 1

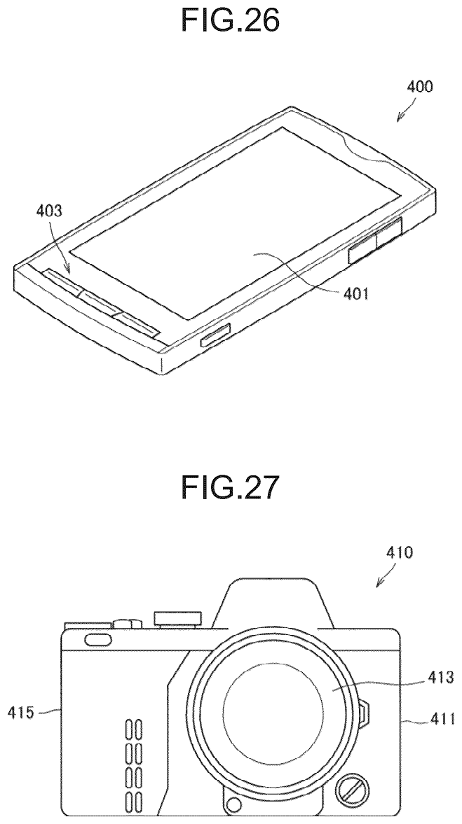

FIG. 26 is a view illustrating an example of an appearance of a smartphone 400. As illustrated in FIG. 26, the smartphone 400 includes a display unit 401 that displays various types of information, and an operation unit 403 including a button or the like that accepts an operation input by a user. The display unit 401 is configured by the display device 1 according to the present embodiment.

### Specific Example 2

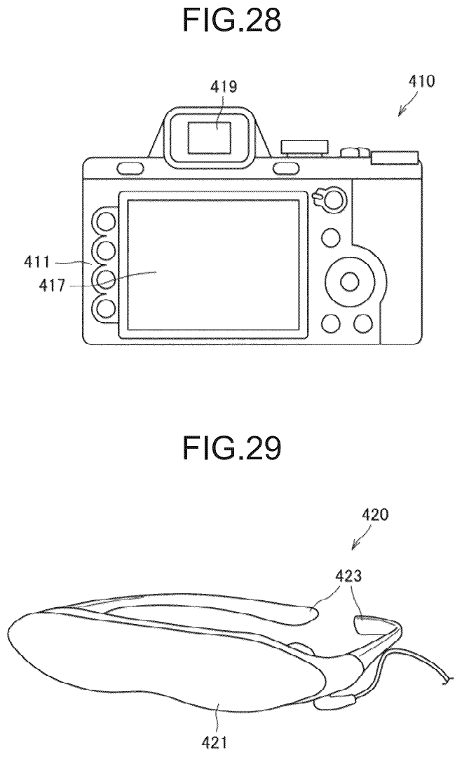

FIGS. 27 and 28 are views each illustrating an example of an appearance of a digital still camera 410. FIG. 27 is a front view of the digital still camera 410, and FIG. 28 is a rear view of the digital still camera 410. As illustrated in FIGS. 27 and 28, the digital still camera 410 is, for example, of a lens interchangeable single lens reflex type, and includes an interchangeable imaging lens unit (interchangeable lens) 413 at substantially the center of the front of a camera body portion (camera body) 411, and a grip portion 415 to be held by a photographer on the front left side.

A monitor 417 is provided at a position shifted to the left side from the center of a back surface of the camera body 411. An electronic viewfinder (eyepiece window) 419 is provided above the monitor 417. By looking into the electronic viewfinder 419, the photographer can determine the composition by visually recognizing an optical image of a subject guided from the imaging lens unit 413. Both or one of the monitor 417 and the electronic viewfinder 419 is configured by the display device 1 according to the embodiment.

### Specific Example 3

FIG. 29 is a view illustrating an example of an appearance of a head mounted display 420. As illustrated in FIG. 29, the head mounted display 420 includes, for example, ear hooking portions 423 to be worn on the user's head at both sides of a glasses-shaped display unit 421. The display unit 421 is configured by the display device 1 according to the embodiment.

### Specific Example 4

FIG. 30 is a view illustrating an example of an appearance of a see-through head mounted display 430. As illustrated in FIG. 30, the see-through head mounted display 430 includes a main body 431, an arm 433, and a lens barrel 435. The main body 431 is connected to the arm 433 and glasses 437. Specifically, an end portion of the main body 431 in the long side direction is coupled to the arm 433, and one side of a side surface of the main body 431 is coupled to the glasses 437 via a connecting member (not illustrated). Note that, the main body 431 may be directly mounted on the head of a human body.

The main body 431 incorporates a control board and a display unit for controlling the operation of the see-through head mounted display 430. The arm 433 connects the main body 431 and the lens barrel 435 to each other and supports the lens barrel 435. Specifically, the arm 433 is coupled to the end portion of the main body 431 and an end portion of the lens barrel 435, and fixes the lens barrel 435. Further, the arm 433 incorporates a signal line for communicating data related to an image provided from the main body 431 to the lens barrel 435.

The lens barrel 435 projects, through the lens of the glasses 437, image light provided from the main body 431 via the arm 433 toward the eyes of the user wearing the see-through head mounted display 430. In the see-through head mounted display 430, the display unit of the main body 431 is configured by the display device 1 according to the embodiment.

### Specific Example 5

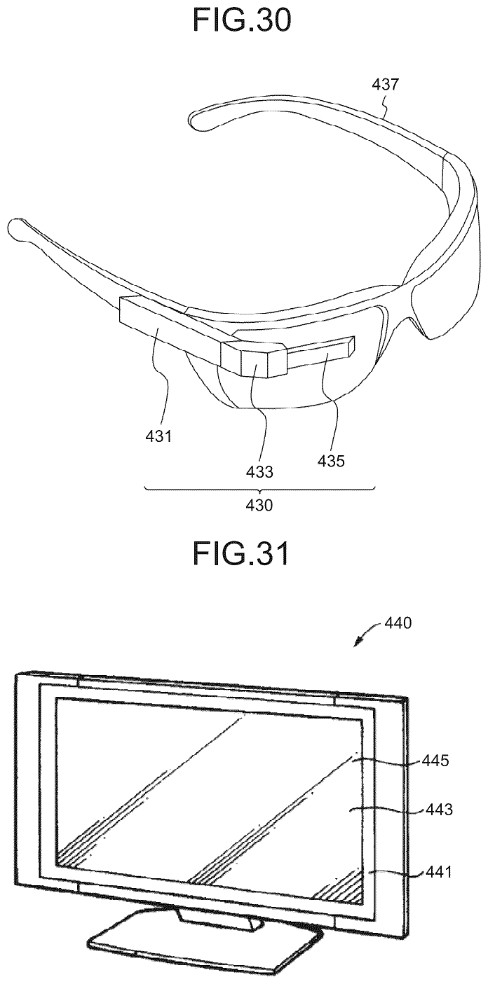

FIG. 31 is a view illustrating an example of an appearance of a television device 440. As illustrated in FIG. 31, the television device 440 includes a video display screen unit 441. The video display screen unit 441 includes, for example, a front panel 443 and a filter glass 445. The video display screen unit 441 is configured by the display device 1 according to the embodiment.

### Specific Example 6

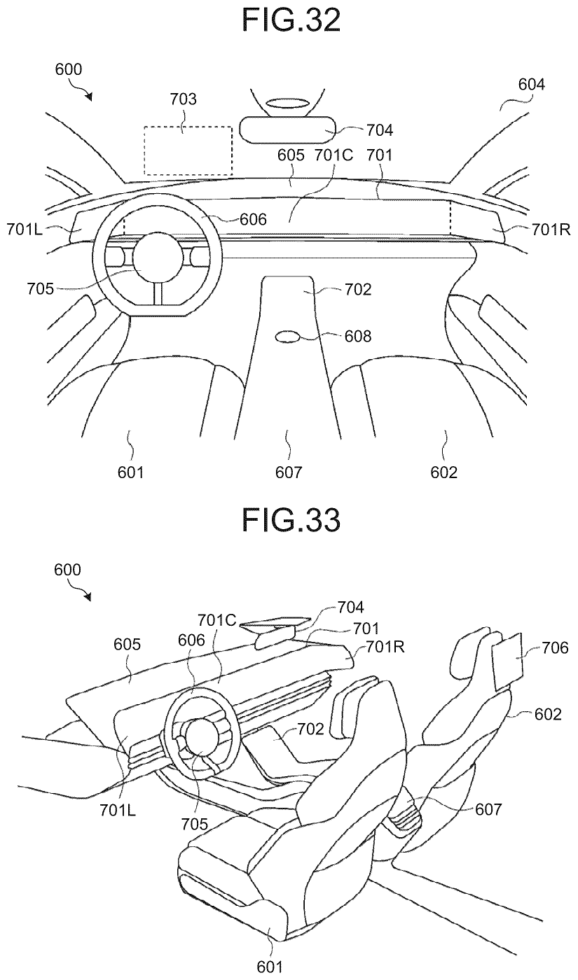

FIGS. 32 and 33 are diagrams each illustrating an internal configuration of a vehicle 600. FIG. 32 illustrates the interior of the vehicle 600 from the rear to the front of the vehicle 600, and FIG. 33 illustrates the interior of the vehicle 600 from the oblique rear to the oblique front of the vehicle 600.

As illustrated in FIGS. 32 and 33, the vehicle 600 includes a center display 701, a console display 702, a head-up display 703, a digital rear mirror 704, a steering wheel display 705, and a rear entertainment display 706. Any or all of these displays 701 to 706 are configured by the display device 1 according to the embodiment.

The center display 701 is disposed on a dashboard 605 at a position facing a driver's seat 601 and a passenger seat 602. FIGS. 32 and 33 illustrate an example of the center display 701 having a horizontally long shape extending from the driver's seat 601 side to the passenger seat 602 side, but the screen size and the arrangement location of the center display 701 are arbitrary. The center display 701 can display information detected by various sensors. As a specific example, the center display 701 can display a captured image captured by an image sensor, a distance image to an obstacle in front of or on a side of the vehicle measured by a ToF sensor, a passenger's body temperature detected by an infrared sensor, and the like. The center display 701 can be used to display, for example, at least one of safety related information, operation related information, a life log, health related information, authentication/identification related information, and entertainment related information.

The safety related information is information such as doze detection, looking-away detection, detection of mischief of a child riding together, whether or not a seat belt is fastened, and detection of leaving of an occupant, and is, for example, information detected by a sensor superimposed on the back side of the center display 701. In the operation related information, a gesture related to an operation of the occupant is detected using the sensor. The detected gesture may include operations of various kinds of equipment in the vehicle 600. For example, operations of air conditioning equipment, a navigation device, an AV device, a lighting device, and the like are detected. The life log includes life logs of all the occupants. For example, the life log includes an action record of each occupant riding in the vehicle. By acquiring and storing the life log, it is possible to check a state of the occupant at the time of an accident. In the health related information, a body temperature of the occupant is detected using a temperature sensor, and a health condition of the occupant is presumed based on the detected body temperature. Alternatively, the health condition of the occupant may be presumed by taking an image of the face of the occupant using an image sensor and presuming the health condition based on the image of the facial expression thus taken. Still alternatively, the health condition of the occupant may be presumed by communicating with the occupant in an automatic voice and presuming the health condition based on an answer of the occupant. The authentication/identification related information includes a keyless entry function of performing face authentication using a sensor, an automatic adjustment function of a sheet height and a position by face identification, and the like. The entertainment related information includes a function of detecting operation information of the AV device by the occupant using the sensor, a function of recognizing the face of the occupant by the sensor and providing content suitable for the occupant by the AV device, and the like.

The console display 702 can be used to display life log information, for example. The console display 702 is disposed near a shift lever 608 of a center console 607 between the driver's seat 601 and the passenger seat 602. The console display 702 can also display information detected by various sensors. In addition, the console display 702 may display an image of the periphery of the vehicle captured by the image sensor, or may display a distance image to an obstacle at the periphery of the vehicle.

The head-up display 703 is virtually displayed behind a windshield 604 in front of the driver's seat 601. The head-up display 703 can be used to display, for example, at least one of safety related information, operation related information, a life log, health related information, authentication/identification related information, and entertainment related information. Since the head-up display 703 is often virtually arranged in front of the driver's seat 601, it is suitable for displaying information directly related to an operation of the vehicle 600 such as the speed of the vehicle 600 and the remaining amount of fuel (battery).

The digital rear mirror 704 can not only display the rear of the vehicle 600 but also display the state of the occupant in the rear seat, and thus can be used to display the life log information, for example, by disposing the sensor so that it is superimposed on the back side of the digital rear mirror 704.

The steering wheel display 705 is disposed near the center of a steering wheel 606 of the vehicle 600. The steering wheel display 705 can be used to display, for example, at least one of safety related information, operation related information, a life log, health related information, authentication/identification related information, and entertainment related information. In particular, since the steering wheel display 705 is located close to the driver's hand, it is suitable for displaying life log information such as the body temperature of the driver, or for displaying information related to the operation of an AV device, an air conditioning unit, and the like.

The rear entertainment display 706 is mounted on the back side of the driver's seat 601 and the passenger seat 602, and is for viewing by the occupant in the rear seat. The rear entertainment display 706 can be used to display, for example, at least one of safety related information, operation related information, a life log, health related information, authentication/identification related information, and entertainment related information. In particular, since the rear entertainment display 706 is located in front of the occupant in the rear seat, information related to the occupant in the back seat is displayed. For example, information related to the operation of the AV device and the air conditioning unit may be displayed, or a result of measuring the body temperature and the like of the occupant in the rear seat by the temperature sensor may be displayed.

As described above, by disposing the sensor so that it is superimposed on the back side of the display, a distance to an object existing in the surroundings can be measured. Optical distance measurement methods are roughly classified into a passive type and an active type. The passive type measures a distance by receiving light from an object without projecting light from the sensor to the object. Examples of the passive type include a lens focus method, a stereo method, and a monocular vision method. The active type measures a distance by projecting light to an object and receiving light from the object by the sensor. Examples of the active type include an optical radar method, an active stereo method, an illuminance difference stereo method, a moiré topography method, and an interference method. The display device 1 according to the embodiment can be applied to any of these types of distance measurement. By using the sensor disposed to be superimposed on the back side of the display device 1 according to the embodiment, the above-described passive or active distance measurement can be performed.

Note that, the electronic apparatus to which the display device 1 according to each embodiment can be applied is not limited to the above examples. The display device 1 according to each embodiment can be applied to a display unit of an electronic apparatus in any field that performs display on the basis of an image signal input from the outside or an image signal generated inside. In other words, the technology according to the present disclosure can be applied to various products. For example, as the vehicle 600 described above, the display device 1 according to each embodiment may be realized as a display unit of any type of mobile body such as an automobile, an electric vehicle, a hybrid electric vehicle, a motorcycle, a bicycle, a personal mobility, an airplane, a drone, a ship, a robot, a construction machine, and an agricultural machine (tractor). Further, for example, the display device 1 according to each embodiment may be applied to a display unit included in an endoscopic surgery system, a microscopic surgery system, or the like.

Although the embodiments, the modifications, the application examples, and the like of the present disclosure have been described in detail with reference to the accompanying drawings, the technical scope of the present disclosure is not limited to such examples. It is obvious that a person having ordinary knowledge in the technical field of the present disclosure can conceive of various changes or modifications within the scope of the technical idea described in the claims, and it is naturally understood that these also belong to the technical scope of the present disclosure.

### 6. Appendix

Note that the present technology can also have the following configurations.
(1)

A light emitting element comprising:
a light emitting unit that outputs light from a light emitting region;
a first lens having a hemispherical shape or a frustum shape and provided above the light emitting region of the light emitting unit; and
a second lens having a frustum shape and provided above the first lens.
(2)

The light emitting element according to (1), wherein
a shape of the second lens is a truncated pyramid.
(3)

The light emitting element according to (1), wherein

a shape of the second lens is a truncated cone.
(4)

The light emitting element according to any one of (1) to (3), wherein
a shape of the first lens is a hemispherical shape and is different from a shape of the second lens.
(5)

The light emitting element according to any one of (1) to (3), wherein
a shape of the first lens is a frustum shape and is the same as a shape of the second lens.
(6)

The light emitting element according to any one of (1) to (3), wherein
a shape of the first lens is a frustum shape and is different from a shape of the second lens.
(7)

The light emitting element according to any one of (1) to (6), further comprising
a filling layer provided between the first lens and the second lens.
(8)

The light emitting element according to (7), wherein
a refractive index of the filling layer is lower than a refractive index of the first lens.
(9)

The light emitting element according to any one of (1) to (8), further comprising
a planarization layer provided on the first lens side of the second lens.
(10)

The light emitting element according to any one of (1) to (9), wherein
a base angle of the second lens is set according to a height of the first lens.
(11)

The light emitting element according to (10), wherein
the base angle of the second lens is set to decrease as the height of the first lens increases.
(12)

The light emitting element according to (10), wherein
the base angle of the second lens is set to increase as the height of the first lens decreases.
(13)

The light emitting element according to any one of (1) to (12), wherein
a base area of the second lens is larger than a base area of the first lens.
(14)

The light emitting element according to any one of (1) to (13), wherein
a central axis that is a normal line passing through a center of the second lens is shifted with respect to a central axis that is a normal line passing through a center of the light emitting unit.
(15)

The light emitting element according to (14), wherein
a central axis that is a normal line passing through a center of the first lens is shifted in the same direction as the central axis of the second lens with respect to the central axis that is the normal line passing through the center of the light emitting unit.
(16)

The light emitting element according to any one of (1) to (15), wherein
two base angles of the second lens in a longitudinal cross section are different.
(17)

A display device comprising
a plurality of light emitting elements, wherein
the plurality of light emitting elements each include
a light emitting unit that outputs light from a light emitting region,
a first lens having a hemispherical shape or a frustum shape and provided above the light emitting region of the light emitting unit, and
a second lens having a frustum shape and provided above the first lens.
(18)

The display device according to (17), wherein
a separation distance between the first lens of a first light emitting element and the first lens of a second light emitting element adjacent to the first light emitting element in the plurality of light emitting elements is 0.25 μm or less.
(19)

The display device according to (17) or (18), wherein
a separation distance between the second lens of a first light emitting element and the second lens of a second light emitting element adjacent to the first light emitting element in the plurality of light emitting elements is 0.1 μm or less.
(20)

An electronic apparatus comprising
a display device including a plurality of light emitting elements, wherein
the plurality of light emitting elements each include
a light emitting unit that outputs light from a light emitting region,
a first lens having a hemispherical shape or a frustum shape and provided above the light emitting region of the light emitting unit, and
a second lens having a frustum shape and provided above the first lens.
(21)

A display device including a plurality of the light emitting elements according to any one of (1) to (16).
(22)

An electronic apparatus including the display device according to (21) or the display device according to any one of (17) to (19).

### REFERENCE SIGNS LIST

1 DISPLAY DEVICE
10 SUBSTRATE
11 HORIZONTAL DRIVE CIRCUIT
12 VERTICAL DRIVE CIRCUIT
20 ANODE LAYER
21 ANODE ELECTRODE
22 INSULATING LAYER
23 CONTACT PLUG
30 ORGANIC LAYER
40 CATHODE LAYER
50 COLOR FILTER LAYER
50B COLOR FILTER
50G COLOR FILTER
50R COLOR FILTER
60 FIRST LENS LAYER
61 FIRST LENS
70 FILLING LAYER
80 PLANARIZATION LAYER
90 SECOND LENS LAYER
91 SECOND LENS
100 SEALING LAYER
110 TRANSPARENT SUBSTRATE
A1 DRIVE CIRCUIT
DTL SIGNAL LINE
EL LIGHT EMITTING UNIT
PS1 FEEDER LINE
PS2 COMMON FEEDER LINE
PX LIGHT EMITTING ELEMENT
PX1 LIGHT EMITTING ELEMENT
SCL SCANNING LINE
TR_{D} DRIVE TRANSISTOR
TR_{W} WRITE TRANSISTOR

1. A light emitting element comprising:
a light emitting unit that outputs light from a light emitting region;
a first lens having a hemispherical shape or a frustum shape and provided above the light emitting region of the light emitting unit; and
a second lens having a frustum shape and provided above the first lens.

2. The light emitting element according to claim 1, wherein
a shape of the second lens is a truncated pyramid.

3. The light emitting element according to claim 1, wherein
a shape of the second lens is a truncated cone.

4. The light emitting element according to claim 1, wherein
a shape of the first lens is a hemispherical shape and is different from a shape of the second lens.

5. The light emitting element according to claim 1, wherein
a shape of the first lens is a frustum shape and is the same as a shape of the second lens.

6. The light emitting element according to claim 1, wherein
a shape of the first lens is a frustum shape and is different from a shape of the second lens.

7. The light emitting element according to claim 1, further comprising
a filling layer provided between the first lens and the second lens.

8. The light emitting element according to claim 7, wherein
a refractive index of the filling layer is lower than a refractive index of the first lens.

9. The light emitting element according to claim 1, further comprising
a planarization layer provided on the first lens side of the second lens.

10. The light emitting element according to claim 1, wherein
a base angle of the second lens is set according to a height of the first lens.

11. The light emitting element according to claim 10, wherein
the base angle of the second lens is set to decrease as the height of the first lens increases.

12. The light emitting element according to claim 10, wherein
the base angle of the second lens is set to increase as the height of the first lens decreases.

13. The light emitting element according to claim 1, wherein
a base area of the second lens is larger than a base area of the first lens.

14. The light emitting element according to claim 1, wherein
a central axis that is a normal line passing through a center of the second lens is shifted with respect to a central axis that is a normal line passing through a center of the light emitting unit.

15. The light emitting element according to claim 14, wherein
a central axis that is a normal line passing through a center of the first lens is shifted in the same direction as the central axis of the second lens with respect to the central axis that is the normal line passing through the center of the light emitting unit.

16. The light emitting element according to claim 1, wherein
two base angles of the second lens in a longitudinal cross section are different.

17. A display device comprising
a plurality of light emitting elements, wherein
the plurality of light emitting elements each include
a light emitting unit that outputs light from a light emitting region,
a first lens having a hemispherical shape or a frustum shape and provided above the light emitting region of the light emitting unit, and
a second lens having a frustum shape and provided above the first lens.

18. The display device according to claim 17, wherein
a separation distance between the first lens of a first light emitting element and the first lens of a second light emitting element adjacent to the first light emitting element in the plurality of light emitting elements is 0.25 μm or less.

19. The display device according to claim 17, wherein
a separation distance between the second lens of a first light emitting element and the second lens of a second light emitting element adjacent to the first light emitting element in the plurality of light emitting elements is 0.1 μm or less.

20. An electronic apparatus comprising
a display device including a plurality of light emitting elements, wherein
the plurality of light emitting elements each include
a light emitting unit that outputs light from a light emitting region,
a first lens having a hemispherical shape or a frustum shape and provided above the light emitting region of the light emitting unit, and
a second lens having a frustum shape and provided above the first lens.
